(19) United States
(12) Patent Application Publication
(10) Pub. No.: US 2007/0200146 A1
(43) Pub. Date: Aug. 30, 2007

(54) Electronic device, method for producing the same, and communication apparatus including the same

(76) Inventors: Keiji Onishi, Osaka (JP); Hiroshi Nakatsuka, Osaka (JP); Takehiko Yamakawa, Osaka (JP)

Correspondence Address: WENDEROTH, LIND & PONACK L.L.P., 2033 K. STREET, NW, SUITE 800, WASHINGTON, DC, 20006, US

(21) Appl. No.: 11/711,052

(22) Filed: Feb. 27, 2007

(30) Foreign Application Priority Data
Feb. 28, 2006 (JP) 2006-051705
Feb. 28, 2006 (JP) 2006-051706

(51) Int. Cl. H01L 27/10

(52) U.S. Cl. 257/202

(57) ABSTRACT

An electronic device according to the present invention includes a functional element acting as a predetermined circuit packaged using a resin member. The electronic device comprises a wiring substrate having a wiring member for electric connection with an external circuit; the functional element mounted on one main surface of the wiring substrate so as to be electrically connected to the wiring member; and the resin member provided on the one main surface of the wiring substrate having the functional element, so as to package the functional element. The resin member includes a filler formed of a magnetic material.

### BACKGROUND OF THE INVENTION

1. Field of the Invention

The present invention relates to an electronic device, a method for producing the same, and a communication apparatus including the same; and more particularly to an electronic device usable for a communication apparatus such as a mobile phone or the like, for example, a filter, a duplexer, and a mechanical switch; a method for producing such an electronic device, and a communication apparatus including such an electronic device.

2. Description of the Background Art

Recently, electronic devices used for communication apparatuses have been required to be more compact and thinner while keeping the level of performance thereof. For example, an electronic device such as a filter, a duplexer or the like for selecting a radio frequency signal used for a mobile phone is required to be compact and to have a smaller insertion loss. As electronic devices fulfilling such requirements, a surface acoustic wave (SAW) device using a surface acoustic wave element as a functional element, and a film bulk acoustic resonator (FBAR) device using a film bulk acoustic wave device as a functional element, are known. As structures of these devices, a structure of packaging a functional element using a resin (for example, Japanese Laid-Open Patent Publications Nos. 2005-73219 and 2006-14099), and a structure of packaging a functional element using a substrate (for example, Japanese PCT National-Phase Laid-Open Patent Publication No. 2004-503164 and Japanese Laid-Open Patent Publication No. 2004-364139) have been proposed. Hereinafter, each of these structures will be described with reference to the drawings.

With reference to FIG. 20 and FIG. 21, conventional electronic devices including a functional element packaged using a resin will be described. FIG. 20 is a cross-sectional view showing a structure of a conventional electronic device 61 as an example of such electronic devices. FIG. 21 is a cross-sectional view showing a structure of a conventional electronic device 71 as another example of such electronic devices.

As shown in FIG. 20, the electronic device 61 includes a wiring substrate 601, an internal terminal 602, a wiring electrode 603, an external terminal 604, a conductive bump 605, a functional element 610, a resin member 620, and a shield layer 630. The functional element 610 includes a base substrate 611 and a base electrode 612. The wiring substrate 601 has a via-hole 601vh therein. The wiring electrode 603 is provided in the via-hole 601vh. The internal terminal 602 is provided on an upper surface of the wiring substrate 601, and the external terminal 604 is provided on a lower surface of the wiring substrate 601. The internal terminal 602 and the external terminal 604 are electrically connected to each other via the wiring electrode 603.

Hereinafter, the structure of the electronic device 61 will be specifically described together with a method for producing the same. First, the base electrode 612 is formed on a lower surface of the base substrate 611, which is a piezoelectric substrate, by vapor deposition, sputtering or the like. Then, the base electrode 612 is patterned by photolithography to form a comb-shaped electrode (not shown) for exciting a surface acoustic wave and an electrode pad (not shown) for electrically connecting the functional element 610 and an external circuit to each other. Next, the functional element 610 is mounted, with the conductive bump 605 interposed therebetween, such that a surface of the functional element 610 having the base electrode 612 faces the upper surface of the wiring substrate 601, with a cavity 610C interposed therebetween. Then, the resin member 620 is provided on the upper surface of the wiring substrate 601 by molding so as to package the functional element 610 and the cavity 610C. The resin member 620 is formed of a resin obtained by mixing a mother material and a filler. As the mother material, an epoxy-based thermosetting resin or the like is usable. As a filler, an insulating non-magnetic material such as silica (SiO₂), alumina (Al₂O₃) or the like is usable. Finally, the shield layer 630 formed of a metal is formed on an upper surface and a side surface of the resin member 620. Owing to the shield layer 630, the electronic device 61 is highly resistive against external noise and moisture.

As shown in FIG. 21, the electronic device 71 includes a wiring substrate 601, an internal terminal 602, a wiring electrode 603, an external terminal 604, a conductive bump 605, a functional element 610, and a resin member 620. The electronic device 71 is different from the electronic device 61 shown in FIG. 20 in not including the shield layer 630 and including a moisture-resistive protection layer (not shown) on the surface of the functional element 610 having the base electrode 612. Owing to the protection layer, the electronic device 71 can be resistive against moisture even though the shield layer 630 is omitted. The electronic device 71, which includes the protection layer instead of the shield layer 630, is more compact than the electronic device 61 while having an equivalent level of moisture resistance.

As described above, the electronic devices 61 and 71 shown in FIG. 20 and FIG. 21 package a functional element using a resin. Owing to such a structure, the electronic devices 61 and 71 are more compact and thinner than electronic devices using a metal or ceramic box-type package.

With reference to FIG. 22 and FIG. 23, conventional electronic devices including a functional element packaged using a substrate will be described. FIG. 22 is a cross-sectional view showing a structure of a conventional electronic device 81 as an example of such electronic devices. FIG. 23 is a cross-sectional view showing a structure of a conventional electronic device 91 as another example of such electronic devices.

As shown in FIG. 22, the electronic device 81 includes a base substrate 811, a first base electrode 812, a piezoelectric layer 813, a second base electrode 814, a lid substrate 820, a wiring electrode 821, an external terminal 822, and a sealing substrate 830. A film bulk acoustic resonator including the first base electrode 812, the piezoelectric layer 813 and the second base electrode 814 is provided on an upper surface of the base substrate 811, which is formed of silicon. A plurality of such film bulk acoustic resonators are provided on the base substrate 811 and are electrically connected to one another. Thus, a filter is formed. The piezoelectric layer 813 is formed of aluminum nitride or the like. The lid substrate 820 is bonded to the upper surface of the base substrate 811 with a glass frit 841. The lid substrate 820 has a via-hole 820vh therein. The wiring electrode 821 is provided in the via-hole 820vh. The external terminal 822 is provided on an upper surface of the lid substrate 820, and is electrically connected to the first base electrode 812 and the second base electrode 814 via the wiring electrode 821. In order not to inhibit mechanical vibration of the film bulk acoustic resonators, a cavity C811 is provided in the base substrate 811, and a cavity C820 is provided below a lower surface of the lid substrate 820. The sealing substrate 830 is bonded to a lower surface of the base substrate 811 with a glass frit 842. Thus, the cavity C811 is sealed.

As shown in FIG. 23, the electronic device 91 includes a substrate 901, an external terminal 902, a wiring electrode 903, a surface acoustic wave resonator 910, an insulating member 921, a first electrode 922, a second electrode 923, conductive members 924 through 926, and bonding members 927 and 928. The insulating members 921 is provided with a capacitor and a coil by the first electrode 922 and the second electrode 923. The surface acoustic wave resonator 910 is electrically connected to the capacitor and coil provided on the insulating member 921 via the conducive member 925. The inductance of the capacitor and coil provided on the insulating members 921 is adjusted by pattern disconnection. Thus, the resonant frequency of the surface acoustic wave resonator 910 is adjusted. The insulating member 921 is bonded to an upper surface of the substrate 901 via the bonding member 927. The surface acoustic wave resonator 910 is bonded to an upper surface of the insulating member 921 via the bonding member 928. A thermal stress, which is caused by a difference between the thermal expansion coefficient of a base substrate included in the surface acoustic wave resonator 910 and the thermal expansion coefficient of the substrate 901, is alleviated by the insulating member 921 and the bonding members 927 and 928. Thus, even when the base substrate and the substrate 901 are thermally expanded, the characteristics of the surface acoustic wave resonator 910 are not changed.

As described above, the electronic devices 81 and 91 shown in FIG. 22 and FIG. 23 package a functional element using a substrate. Owing to such a structure, the electronic devices 81 and 91 are more compact and thinner than electronic devices using a metal or ceramic box-type package.

The electronic device 61 shown in FIG. 20 includes the shield layer 630. Therefore, the electronic device 61 has problems of being larger than the electronic device 71 shown in FIG. 21 by the thickness of the shield layer 630, and of requiring a larger number of steps of production due to the formation of the shield layer 30.

The electronic device 71 is more compact and is produced by a smaller number of steps than the electronic device 61. However, because the shield layer 630 is omitted, the electronic device 71 has a lower level of linearity. When used for a communication apparatus of a mobile phone or the like, the electronic device 71 has a problem of having a lower intermodulation distortion characteristic. The intermodulation distortion characteristic is related to an intermodulation distortion which is generated, when an electronic device is used in a communication apparatus, by a transmission signal transmitted from the communication apparatus and an interference wave coming from outside through an antenna, for example.

As described above, with the conventional electronic devices 61 and 71 packaging a functional element using a resin, it is difficult to realize the compactness and thinness while suppressing the deterioration of the intermodulation distortion characteristic thereof.

The conventional electronic devices 81 and 91 shown in FIG. 22 and FIG. 23 packaging a functional element using a substrate are designed only to realize the compactness and thinness but not to suppress the deterioration of the intermodulation distortion characteristic thereof. Therefore, the electronic devices 81 and 91 do not have a superb intermodulation distortion characteristic.

### SUMMARY OF THE INVENTION

Therefore, an object of the present invention is to provide an electronic device including a functional element packaged using a resin, which is compact and thin while suppressing the deterioration of the intermodulation distortion characteristic thereof, a communication apparatus including such an electronic device, and a method for producing such an electronic device.

Another object of the present invention is to provide an electronic device including a functional element packaged using a substrate, which has a superb intermodulation distortion characteristic, a communication apparatus including such an electronic device, and a method for producing such an electronic device.

A first aspect of the present invention is directed to an electronic device. In order to solve the above-described problems, the first aspect of the present invention is directed to an electronic device including a functional element acting as a predetermined circuit packaged using a resin member. The electronic device comprises a wiring substrate having a wiring member for electric connection with an external circuit; the functional element mounted on one main surface of the wiring substrate so as to be electrically connected to the wiring member; and the resin member provided on the one main surface of the wiring substrate having the functional element, so as to package the functional element. The resin member includes a filler formed of a magnetic material.

Thus, the non linearity of the electronic device can be improved without using the shield layer. When the electronic device is used in a communication apparatus, the intermodulation distortion characteristic can be significantly improved against various interference waves. As a result, the electronic device can realize the compactness and thinness while suppressing the deterioration of the intermodulation distortion characteristic thereof. Since the resin member includes a filler formed of a magnetic material, the attenuation outside the passband of the electronic device and radio frequency range characteristics including isolation can be improved.

Preferably, the filler is formed of a conductive magnetic material covered with an insulating material. Owing to this, the wiring member is prevented from being short circuited. The changes in the magnetic characteristics and various other over-time changes of the magnetic material can also be suppressed. Preferably, the filler is formed of an organic material carrying the magnetic material. Owing to this, the affinity between the filler and the epoxy-based thermosetting resin as a mother material is enhanced, which improves the reliability of the electronic device. Preferably, the magnetic material has a chemical formula including at least one chemical element selected from nickel, iron, chromium, cobalt and manganese.

Preferably, the functional element is a passive element. Preferably, the functional element acts as a filter using elastic vibration. Owing to this, an electronic device including a filter having a superb intermodulation distortion characteristic can be provided. Preferably, the functional element acts as a mechanical switch. Owing to this, an electronic device including a mechanical switch having a superb intermodulation distortion characteristic can be provided. Two of the functional element may be provided on one main surface of the wiring substrate; and the two functional elements respectively may act as band-pass filters having different passbands from each other. Owing to this, an electronic device including a duplexer having a superb intermodulation distortion characteristic can be provided.

Preferably, the electronic device according to the first aspect of the present invention is included in a communication apparatus comprising an antenna; a transmission circuit; and a receiving circuit. The electronic device according to the first aspect of the present invention is included in at least one of a connection section of the antenna with the transmission circuit and the receiving circuit, a connection section of the antenna and the transmission circuit, and a connection section of the antenna and the receiving circuit. Owing to this, a communication apparatus having superb voice quality can be provided.

The first aspect of the present invention is also directed to a method for producing an electronic device. In order to solve the above-described problems, the first aspect of the present invention is directed to a method for producing an electronic device including a functional element acting as a predetermined circuit packaged using a resin member. The method comprises the steps of mounting the functional element on one main surface of a wiring substrate having a wiring member for electric connection with an external circuit, such that the functional element is electrically connected to the wiring member; and forming the resin member including a filler formed of a magnetic material on the one main surface of the wiring substrate having the functional element, such that the functional element is packaged.

A second aspect of the present invention is directed to an electronic device. In order to solve the above-described problems, the second aspect of the present invention is directed to an electronic device including a part of a functional element acting as a predetermined circuit packaged using a recessed substrate having a recess in one main surface thereof. The electronic device comprises the functional element including at least a base substrate and a base electrode provided on one main surface of the base substrate, the base electrode having a pattern in accordance with the predetermined circuit; the recessed substrate provided on the main surface of the base substrate so as to locate the base electrode in the recess and package the base electrode; and a wiring electrode, provided in a via-hole formed in one of the base substrate and the recessed substrate, for electrically connecting the functional element and an external circuit to each other. At least a part of the wiring electrode is formed of a magnetic material.

Thus, the nonlinearity of the electronic device can be improved. When the electronic device is used in a communication apparatus, the intermodulation distortion characteristic can be significantly improved against various interference waves. Since at least a part of the wiring electrode is formed of a magnetic material, the intermodulation distortion characteristic can be significantly improved without changing the size of the electronic device from that of the conventional electronic devices.

Preferably, the electronic device further comprise a magnetic layer provided on at least one of, on a main surface of the base substrate opposite to the main surface thereof having the base electrode, and on a main surface of the recessed substrate opposite to the main surface thereof having the recess. Since the step of forming the magnetic layer on a main surface of the base substrate or a recessed substrate is simple, an electronic device having a more superb intermodulation distortion characteristic can be provided at low cost. Preferably, at least a part of an outer part of the wiring electrode in contact with the via-hole is formed of a magnetic material. Preferably, the wiring electrode is entirely formed of a conductive magnetic material. Preferably, the wiring electrode includes an input electrode for inputting an electric signal which is output from the external circuit; an output electrode for outputting an electric signal to the external circuit; and a grounding electrode. At least a part of at least one of the input electrode and the output electrode is formed of a magnetic material. Owing to this, the intermodulation distortion characteristic of the electronic device can be efficiently improved. Preferably, the magnetic material has a chemical formula including at least one chemical element selected from nickel, iron, chromium, cobalt and manganese. Preferably, a part of the wiring electrode is formed of a magnetic material covered with an insulating material. Owing to this, changes in the magnetic characteristics and various other over-time changes of the magnetic material can be suppressed. Preferably, a part of the wiring electrode is formed of an organic material carrying the magnetic material.

Preferably, the functional element is a passive element. Preferably, the base electrode includes a pattern in accordance with a filter; and the functional element acts as a filter using elastic vibration. Owing to this, an electronic device including a filter having a superb intermodulation distortion characteristic can be provided. Preferably, the base electrode includes a pattern in accordance with a mechanical switch; and the functional element acts as a mechanical switch. Owing to this, an electronic device including a mechanical switch having a superb intermodulation distortion characteristic can be provided. Preferably, the base electrode includes a plurality of patterns in accordance with band-pass filters having different passbands from each other; and the functional element acts as a duplexer including the band-pass filters. Owing to this, an electronic device including a duplexer having a superb intermodulation distortion characteristic can be provided.

Preferably, the electronic device according to the second aspect of the present invention is included in a communication apparatus comprising an antenna; a transmission circuit; and a receiving circuit. The electronic device according to the second aspect of the present invention is included in at least one of a connection section of the antenna with the transmission circuit and the receiving circuit, a connection section of the antenna and the transmission circuit, and a connection section of the antenna and the receiving circuit. Owing to this, a communication apparatus having superb voice quality can be provided.

The second aspect of the present invention is also directed to a method for producing an electronic device. In order to solve the above-described problems, the second aspect of the present invention is directed to a method for producing an electronic device including a part of a functional element acting as a predetermined circuit packaged using a recessed substrate having a recess in one main surface thereof. The method comprises the steps of forming a base electrode, including a pattern in accordance with the predetermined circuit of the functional element, on one main surface of the base substrate; locating the recessed substrate on the main surface of the base substrate so as to locate the base electrode in the recess and package the base electrode; forming a via-hole in one of the base substrate and the recessed substrate; and forming a wiring electrode for electrically connecting the functional element and an external circuit to each other in the via-hole, the wiring electrode being at least partially formed of a magnetic material.

According to the present invention, an electronic device including a functional element packaged using a resin, which is compact and thin while suppressing the deterioration of the intermodulation distortion characteristic thereof, a communication apparatus including such an electronic device, and a method for producing such an electronic device are provided.

Also according to the present invention, an electronic device including a functional element packaged using a substrate, which has a superb intermodulation distortion characteristic, a communication apparatus including such an electronic device, and a method for producing such an electronic device can be provided.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view showing an exemplary structure of an electronic device 11, according to an embodiment of the present invention, including a surface acoustic wave element as a functional element packaged using a resin member;

FIG. 2A shows an exemplary configuration of a ladder-type circuit of a band-pass filter;

FIG. 2B shows an exemplary configuration of a lattice-type circuit of a band-pass filter;

FIG. 3 is a cross-sectional view showing an exemplary structure of an electronic device 12, according to an embodiment of the present invention, including a duplexer;

FIG. 4 is a functional block diagram of the electronic device 12 shown in FIG. 3;

FIG. 5 is a functional block diagram of a communication apparatus 41 including the electronic device 12 shown in FIG. 3;

FIG. 6 is a functional block diagram of a communication apparatus 41 including the electronic device 12 shown in FIG. 3 and band-pass filters 417 and 418 included in the electronic device 11 shown in FIG. 1;

FIG. 7 shows an exemplary structure of a measuring system for measuring intermodulation distortion characteristics;

FIG. 8 is a cross-sectional view showing an exemplary structure of an electronic device 13, according to an embodiment of the present invention, including a mechanical switch;

FIG. 9 is a functional block diagram of a communication apparatus 43 including the electronic device 13 shown in FIG. 8;

FIG. 10 is a cross-sectional view showing an exemplary structure of an electronic device 11a, according to an embodiment of the present invention, including a filter using a film bulk acoustic wave element;

FIG. 11 is a cross-sectional view showing an exemplary structure of an electronic device 12a, according to an embodiment of the present invention, including a duplexer using a film bulk acoustic wave element;

FIG. 12 is a cross-sectional view showing an exemplary structure of an electronic device 51, according to an embodiment of the present invention, including a film bulk acoustic wave element as a functional element packaged using a substrate;

FIG. 13 is a cross-sectional view showing an exemplary structure of an electronic device 52, according to an embodiment of the present invention, including a duplexer;

FIG. 14 is a cross-sectional view showing an exemplary structure of an electronic device 53, according to an embodiment of the present invention, including a mechanical switch;

FIG. 15 is a cross-sectional view showing an exemplary structure of an electronic device 51, according to an embodiment of the present invention, in which a magnetic layer 5031 is provided on a side wall of a via-hole 561vh;

FIG. 16 is a cross-sectional view showing an exemplary structure of an electronic device 52, according to an embodiment of the present invention, in which a wiring electrode 103 is entirely formed of a magnetic material;

FIG. 17 is a cross-sectional view showing an exemplary structure of an electronic device 51, according to an embodiment of the present invention, in which a via-hole is provided on a lid substrate 530;

FIG. 18 is a cross-sectional view showing an exemplary structure of an electronic device 51a, according to an embodiment of the present invention, including a filter using a surface acoustic wave element;

FIG. 19 is a cross-sectional view showing an exemplary structure of an electronic device 52a, according to an embodiment of the present invention, including a duplexer using a surface acoustic wave element;

FIG. 20 is a cross-sectional view showing a structure of an exemplary conventional electronic device 61;

FIG. 21 is a cross-sectional view showing a structure of another exemplary conventional electronic device 71;

FIG. 22 is a cross-sectional view showing a structure of a still another exemplary conventional electronic device 81; and

FIG. 23 is a cross-sectional view showing a structure of still another exemplary conventional electronic device 91.

### DESCRIPTION OF THE PREFERRED EMBODIMENTS

Hereinafter, embodiments of the present invention will be described with reference to the drawings. In a first embodiment, electronic devices including a functional element packaged using a resin will be described. In a second embodiment, electronic devices including a functional element packaged using a substrate will be described. In the first and second embodiments, the electronic devices use a passive element as a functional element. Specifically, the electronic devices use, as a functional element, a surface acoustic wave element using a surface acoustic wave resonator, a film bulk acoustic wave element using a film bulk acoustic resonator, and a mechanical switch, for example. The mechanical switch is a radio frequency switch based on a MEMS (Micro Electro-Mechanical System) or the like used for a communication apparatuses.

### First Embodiment

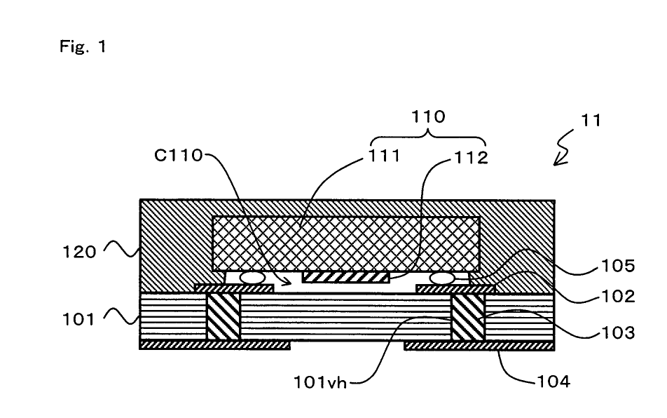

With reference to FIG. 1, an electronic device including a surface acoustic wave element as a functional element packaged using a resin member will be described. FIG. 1 is across-sectional view showing an exemplary structure of an electronic device 11 including a surface acoustic wave element as a functional element packaged using a resin member. As shown in FIG. 1, the electronic device 11 includes a wiring substrate 101, an internal terminal 102, a wiring electrode 103, an external terminal 104, a conductive bump 105, a functional element 110, and a resin member 120.

The functional element 110 includes a base substrate 111 and a base electrode 112. The base substrate 111 is, for example, a piezoelectric substrate. The piezoelectric substrate is formed of a piezoelectric single crystalline material such as lithium tantalate, lithium niobate, potassium niobate or the like. Alternatively, the base substrate 111 may be, for example, a silicon substrate, a sapphire substrate or a glass substrate having a piezoelectric thin film formed thereon. The piezoelectric thin film may be formed of aluminum nitride (AlN), zinc oxide (ZnO), lead zirconate titanate (PZT) or the like.

The base electrode 112 is formed of a layer of aluminum or the like, and is provided on a lower surface of the base substrate 111. The base electrode 112 is patterned to form a comb-like electrode for exciting a surface acoustic wave and a plurality of electrode pads for electrically connecting the functional element 110 and an external circuit to each other. The electrode pads include an input pad for inputting an electric signal from outside, an output pad for outputting an electric signal to outside, and a grounding pad. In the functional element 110, a surface acoustic wave resonator is formed of the comb-like electrode included in the base electrode 112 and the base substrate 111.

The functional element 110 is formed as follows. First, the base electrode 112, which is not patterned, is formed on the lower surface of the base substrate 111 by vapor deposition, sputtering or the like. Then, the base electrode 112 is patterned by usual photolithography to form the comb-like electrode and the electrode pads. Next, an upper surface of the base substrate 111 is processed with back-grinding by chemical mechanical polishing (CMP). In this embodiment, the base substrate 111 is processed to have a thickness of about 150 μm.

The wiring substrate 101 is formed of alumina, low temperature baked ceramic containing a glass component, resin or silicon interposer or the like. The wiring substrate 101 has a thickness of about 200 μm. The internal terminal 102 is formed on an upper surface of the wiring substrate 101. The external terminal 104 is formed on a lower surface of the wiring substrate 101. The wiring substrate 101 has via-holes 101vh therein, which are formed by deep-RIE. The via-holes 101vh are respectively provided in correspondence with the input pad, the output pad and the grounding pad of the base electrode 112. In each via-hole 101vh, the wiring electrode 103 formed of a conductive material is provided. The wiring electrodes 103 include an input electrode corresponding to the input pad, an output electrode corresponding to the output pad, and a grounding electrode corresponding to the grounding pad. The internal terminal 102 and the external terminal 104 are electrically connected to each other via the wiring electrode 103.

The conductive bump 105 is formed of solder, gold or the like. The functional element 110 is mounted on the wiring substrate 101 in a face-down manner, with the conductive bump 105 interposed therebetween. The functional element 110 is mounted in a face-down manner as follows. First, the conductive bump 105 is formed of solder on the internal terminal 102. Then, the functional element 110 is located such that the main surface thereof having the base electrode 112 faces the wiring substrate 101. The main surface of the functional element 110 having the base electrode 112 is a vibration surface at which elastic vibration is generated. Then, the conductive bump 105 is heated to make the functional element 110 and the internal terminal 102 electrically conductive to each other. As understood from this, the internal terminal 102, the wiring electrodes 103, the external terminal 104 and the conductive bump 105 are wiring members for electrically connecting the functional element 110 and an external circuit to each other. A cavity C110 is provided between a lower surface of the functional element 110 and the upper surface of the wiring substrate 101, in order not to inhibit elastic vibration of the functional element 110.

The resin member 120 is obtained by mixing a mother material and a filler. The mother material is an epoxy-based thermosetting resin, an epoxy-based thermoplastic resin or the like. The filler is, for example, a magnetic material. As the magnetic material, iron (Fe), permalloy (Fe—Ni), MnZn ferrite, chromium oxide or the like is usable. More specifically, the magnetic material has a chemical formula including at least one chemical element selected from nickel (Ni), iron (Fe), chromium (Cr), cobalt (Co) and manganese (Mn). The resin member 120 is obtained by pulverizing such a magnetic material and adding as a filler to an epoxy-based thermosetting resin or the like. The resin member 120 is formed on the upper surface of the wiring substrate 101 so as to package the functional element 110 and the cavity C110. Specifically, the resin member 120 is provided by molding so as to contact an upper surface and a side surface of the functional element 110 and an area of the upper surface of the wiring substrate 101 which does not face the functional element 110. Thus, the resin member 120 seals the functional element 110. The resin member 120 may be formed by a usual printing method, a method of heating and pressing the resin member 120 formed into a sheet in advance, or the like.

The filler is described above as being formed of a magnetic material, but is not limited to this. The filler may be formed of an organic material carrying a magnetic metal as a magnetic material. In this case, the affinity between the filler and the epoxy-based thermosetting resin or the like as a mother material, which improves the reliability of the electronic device 11.

In the case where the filler is formed of a conductive magnetic material such as iron or the like, when the content of the filler is high to some extent, a plurality of the internal terminals 102 may be electrically shortcircuited. In order to avoid this, it is preferable to cover the magnetic material with an inorganic insulating material (for example, silicon oxide or an oxide film of the magnetic material). Specifically, the surface of each particle of the magnetic material is covered with the inorganic insulating material. When the magnetic material is covered with the inorganic insulating material, changes in the magnetic characteristics and various other over-time changes of the magnetic material can also be suppressed.

Next, a method for producing the electronic device 11 shown in FIG. 1 will be generally described. First, the via-holes 101vh are formed in the wiring substrate 101 by deep-RIE. Then, the wiring electrodes 103 are respectively formed in the via-holes 101vh formed in the wiring substrate 101. The internal terminal 102 is formed on the upper surface of the wiring substrate 101, and the external terminal 104 is formed on the lower surface of the wiring substrate 101. Next, the functional element 110 is mounted on the wiring substrate 101 in a face-down manner, with the conductive bump 105 interposed therebetween. Then, the resin member 120 is formed on the wiring substrate 101 so as to package the functional element 110 and the cavity C110. Thus, the electronic device 11 shown in FIG. 1 is obtained.

Hereinafter, as specific examples of the electronic device according to this embodiment, cases in which the electronic device includes each of a filter, a duplexer, and a mechanical switch will be described.

(Filter)

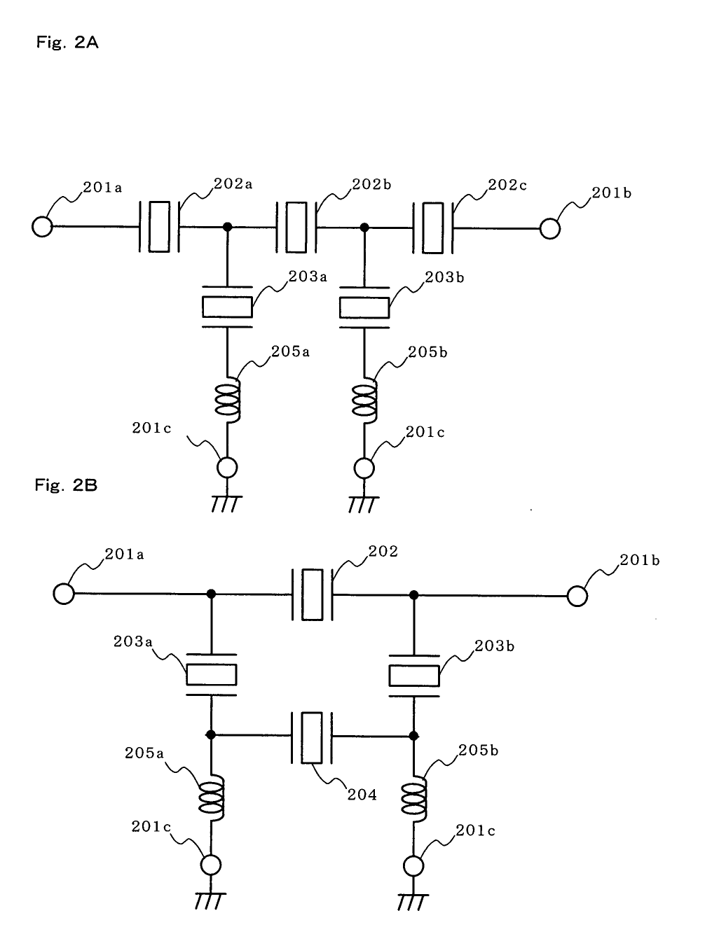

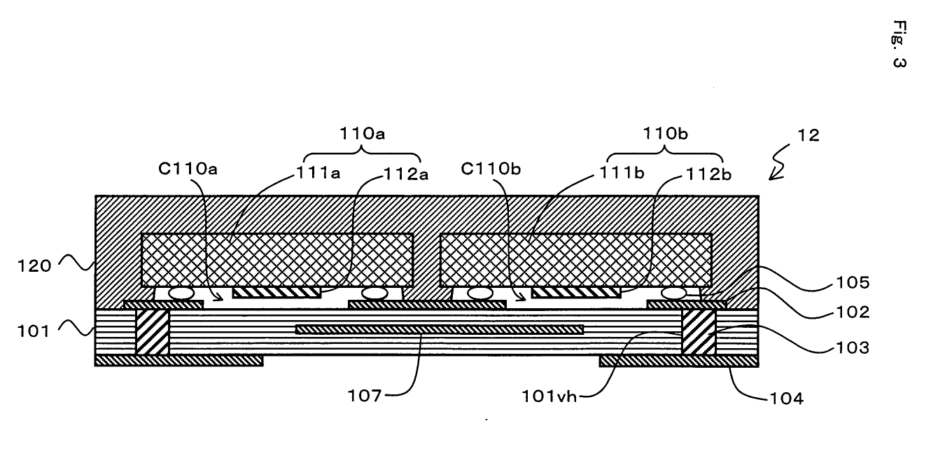

With reference to FIG. 1 again, a case in which the electronic device according to this embodiment includes a filter will be described. In this case, the base electrode 112 includes a plurality of comb-like electrodes. Thus, in the functional element 110, a plurality of surface acoustic wave resonators are formed of the plurality of comb-like electrodes and the base substrate 111. The plurality of surface acoustic wave resonators are electrically connected to one another, so that the functional element 110 acts as a filter. Thus, the electronic device 11 includes a filter. The functional element 110 may act as, for example, a high-pass filter, a low-pass filter or a band-pass filter. For example, the functional element 110 can act as a band-pass filter by electrically connecting the plurality of surface acoustic wave resonators to one another as shown in FIG. 2A or FIG. 2B. FIG. 2A shows a ladder-type circuit, which is one exemplary circuit configuration of the band-pass filter. FIG. 2B shows a lattice-type circuit, which is another exemplary circuit configuration of the band-pass filter. In FIG. 2A and FIG. 2B, an input terminal 201a corresponds to the input pad, an output terminal 201b corresponds to the output pad, and grounding terminals 201c each correspond to the grounding pad.

Referring to FIG. 2A, series resonators 202a, 202b and 202c are connected in series between the input terminal 201a and the output terminal 201b. Between the series resonators 202a and 202b, one terminal of a parallel resonator 203a is connected in parallel, and the other terminal of the parallel resonator 203a is grounded via an inductor 205a and the grounding terminal 201c. Between the series resonators 202b and 202c, one terminal of a parallel resonator 203b is connected in parallel, and the other terminal of the parallel resonator 203b is grounded via an inductor 205b and the grounding terminal 201c. In this manner, the series resonators 202a, 202b and 202c and the parallel resonators 203a and 203b are each formed of a surface acoustic wave resonator, so that the functional element 110 acts as a band-pass filter.

Referring to FIG. 2B, a series resonator 202 is connected between the input terminal 201a and the output terminal 201b. Between the input terminal 201a and the series resonator 202, one terminal of a parallel resonator 203a is connected in parallel, and the other terminal of the parallel resonator 203a is grounded via an inductor 205a and the grounding terminal 201c. Between the output terminal 201b and the series resonator 202, one terminal of a parallel resonator 203b is connected in parallel, and the other terminal of the parallel resonator 203b is grounded via an inductor 205b and the grounding terminal 201c. One terminal of the inductor 205a which is not grounded, and one terminal of the inductor 205b which is not grounded, are connected to each other via a bypass resonator 204. In this manner, the series resonator 202, the parallel resonators 203a and 203b, and the bypass resonator 204 are each formed of a surface acoustic wave resonator, so that the functional element 110 acts as a band-pass filter.

The inductors 205a and 205b shown in FIG. 2A and FIG. 2B are formed of parasitic inductors or external inductors. The circuit configuration of the band-pass filter is not limited to those shown in FIG. 2A and FIG. 2B.

(Duplexer)

With reference to FIG. 3, a case in which the electronic device according to this embodiment includes a duplexer will be described. FIG. 3 is a cross-sectional view showing an exemplary structure of an electronic device 12 according to this embodiment, which includes a duplexer. As shown in FIG. 3, the electronic device 12 includes a wiring substrate 101, an internal terminal 102, a wiring electrode 103, an external terminal 104, a conductive bump 105, functional elements 110a and 110b, an internal layer electrode 107, and a resin member 120. The electronic device 12 shown in FIG. 3 is mainly different from the electronic device 11 shown in FIG. 1 in including the functional elements 110a and 110b and the internal layer electrode 107. In FIG. 3, identical elements to those of the electronic device 11 shown in FIG. 1 bear identical reference numerals thereto, and detailed descriptions thereof will be omitted.

The functional element 110a includes a base substrate 111a and a base electrode 112a. The base substrate 111a is, for example, a piezoelectric substrate. The base electrode 112a includes a plurality of comb-like electrodes. In the functional element 110a, a plurality of surface acoustic wave resonators are formed of the plurality of comb-like electrodes included in the base electrode 112a and the base substrate 111a. The plurality of surface acoustic wave resonators are electrically connected to one another, so that the functional element 110a acts as a transmission filter (Tx), which is a band-pass filter having a predetermined passband. The functional element 110a is mounted on the wiring substrate 101 in a face-down manner, with the conductive bump 105 interposed therebetween. A cavity C110a is provided between a lower surface of the functional element 110a and an upper surface of the wiring substrate 101, in order not to inhibit elastic vibration of the functional element 110a. The functional element 110b includes a base substrate 111b and a base electrode 112b. The base substrate 111b is, for example, a piezoelectric substrate. The base electrode 112b includes a plurality of comb-like electrodes. In the functional element 110b, a plurality of surface acoustic wave resonators are formed of the plurality of comb-like electrodes included in the base electrode 112b and the base substrate 111b. The plurality of surface acoustic wave resonators are electrically connected to one another, so that the functional element 110b acts as a receiving filter (Rx), which is a band-pass filter having a passband which is different from that of the transmission filter (Tx). The functional element 110b is mounted on the wiring substrate 101 in a face-down manner, with the conductive bump 105 interposed therebetween. A cavity C110b is provided between a lower surface of the functional element 110b and the upper surface of the wiring substrate 101, in order not to inhibit elastic vibration of the functional element 110b. The resin member 120 is formed on the upper surface of the wiring substrate 101 so as to package the functional element 110a, the cavity C110a, the functional element 110b and the cavity C110b. The internal layer electrode 107 is formed in the wiring substrate 101 and forms a phase shift circuit (transmission line). In this manner, the functional element 110a acts as a transmission filter, the functional element 110b acts as a receiving filter, and the internal layer electrode 107 acts as a phase shift circuit. Thus, the electronic device 12 includes a duplexer.

In FIG. 3, one electronic device 12 includes a duplexer, but the duplexer is not limited to this. For example, a duplexer may be formed by connecting an electronic device 11 including a transmission filter and another electronic device 11 including a receiving filter to each other on another substrate such as a mother substrate or the like. The structure shown in FIG. 3 in which one electronic device 12 includes a duplexer has a smaller size.

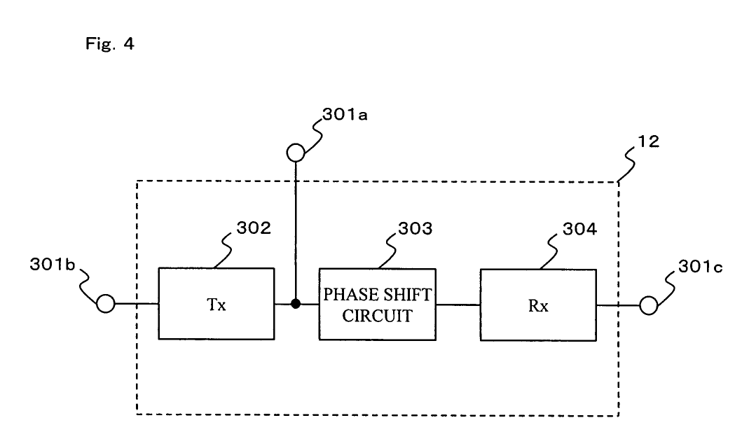

FIG. 4 is a functional block diagram of the electronic device 12 shown in FIG. 3. Referring to FIG. 4, an antenna terminal 301a connected to an antenna, a transmission terminal 301b to which a transmission signal is input, and a receiving terminal 301c for outputting a receiving signal are each formed of an electrode pad formed in the base electrode 111a or 111b. A transmission filter (Tx) 302 is formed of the functional element 110a, a phase shift circuit 303 is formed of the internal layer electrode 107, and a receiving filter (Rx) 304 is formed of the functional element 110b.

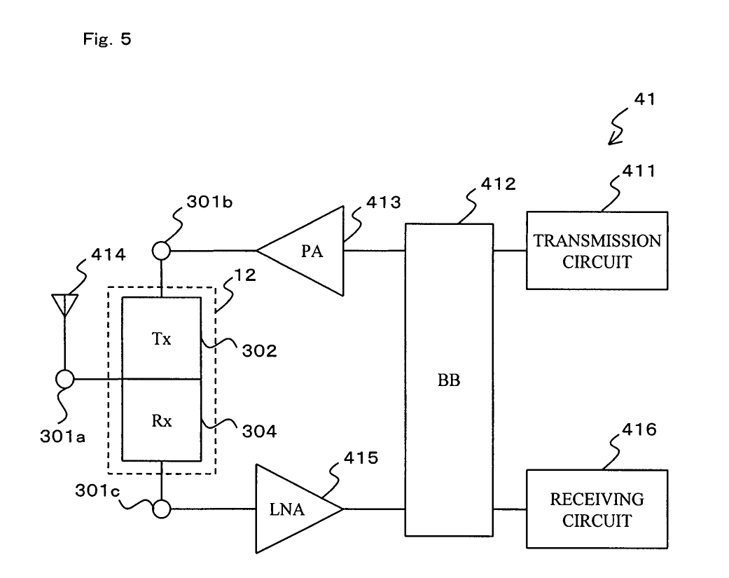

FIG. 5 is a functional block diagram of a communication apparatus 41 including the electronic device 12 shown in FIG. 3. The communication apparatus 41 shown in FIG. 5 is capable of simultaneously transmitting and receiving wireless signals, and is, for example, a mobile phone. As shown in FIG. 5, the communication apparatus 41 includes a transmission circuit 411, a baseband (BB) section 412, a power amplifier (PA) 413, the electronic device 12, an antenna 414, a low noise amplifier (LNA) 415, and a receiving circuit 416. As shown in FIG. 5, the electronic device 12 is in at a connection section of the antenna 414 with the transmission circuit 411 and the receiving circuit 416. FIG. 5 omits the phase shift circuit 303 among the functional blocks of the electronic device 12 shown in FIG. 4.

A transmission signal which is output from the transmission circuit 411 is modified by the baseband section 412, and is amplified by the power amplifier 413. The transmission signal which is amplified by the power amplifier 413 is output to the transmission filter 302 via the transmission terminal 301b, and is filtered by the transmission filter 302. The transmission signal which is filtered by the transmission filter 302 is transmitted as a radio wave from the antenna 414 via the antenna terminal 301a. The electronic device 12 is designed to prevent the transmission signal filtered by the transmission filter 302 from being input to the receiving filter 304 at this point. A receiving signal which is received by the antenna 414 is output to the receiving filter 304 via the antenna terminal 301a without being input to the transmission filter 302. The receiving signal which is output to the receiving filter 304 is filtered by the receiving filter 304, and is output to the low noise amplifier 415 via the receiving terminal 301c. The receiving signal which is output to the low noise amplifier 415 is amplified by the low noise amplifier 415, and is demodulated by the baseband section 412. The receiving signal which is demodulated by the baseband section 412 is output to the receiving circuit 416.

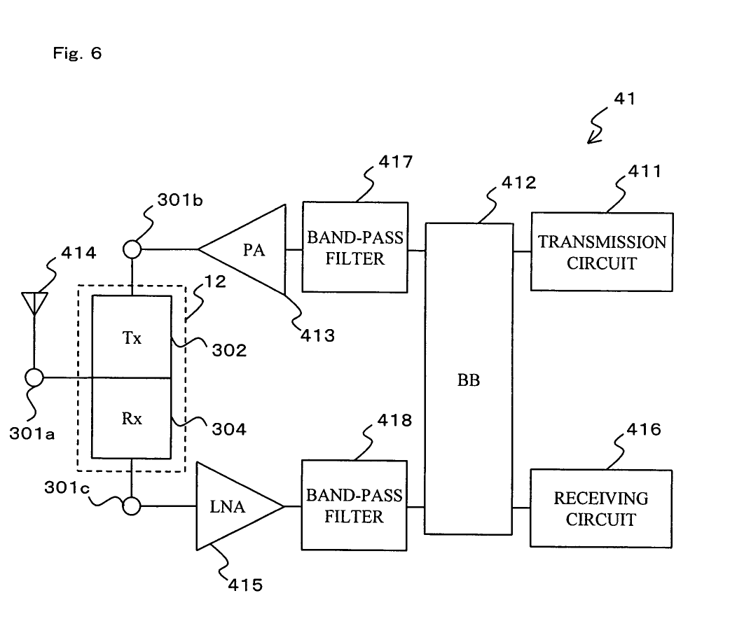

As shown in FIG. 6, the communication apparatus 41 shown in FIG. 5 may further include band-pass filters 417 and 418, which are included in the electronic device 11 shown in FIG. 1. FIG. 6 is a functional block diagram of a communication apparatus 41 including the band-pass filters 417 and 418 in addition to the structure shown in FIG. 5. The band-pass filters 417 and 418 are included in the electronic device 11 shown in FIG. 1. The band-pass filter 417 is located between the baseband section 412 and the power amplifier 413. The band-pass filter 418 is provided between the baseband section 412 and the low noise amplifier 415. The communication apparatus 41 does not need to include both the band-pass filters 417 and 418, and may include either the band-pass filter 417 or 418.

Here, intermodulation distortion, which is generated in general communication apparatuses, will be described together with the problems caused by intermodulation distortion. In a situation where there are a plurality of channels or systems using various wireless frequencies, an antenna receives signals of various frequency components (interference signals). When, for example, a transmission signal is output from a communication apparatus in this situation, the antenna receives the transmission signal and interference signals. At this time, the transmission signal and interference signals are distorted by the nonlinearity of an electronic device including the duplexer or other components. Such distortion generates intermodulation distortion. Now, a specific case in which two signals of different frequencies (fa, fb) are input to an electronic device including a duplexer will be described. In this case, the two signals are distorted by the nonlinearity of the electronic device, and secondary harmonics (2fa, s2b) are generated. The secondary harmonics and the fundamental waves (fa, fb) generate signals having frequencies of (2fa-fb), (2fb-fa) and the like as tertiary intermodulation distortion (IM3). In the case where the frequency of such intermodulation distortion is within the passband of the receiving filter, the intermodulation distortion passes the receiving filter. As a result, the signal receiving level of the receiving circuit is lowered.

A conventional duplexer using a metal package or a large ceramic package includes a shield layer, and so the signal level of the intermodulation distortion is kept acceptable. In order to reduce the size and thickness of electronic devices, a duplexer including no shield layer is now used for communication apparatuses. This deteriorates the linearity of the duplexer itself. As a result, the signal level of the intermodulation distortion is increased to an unacceptable level. Such a level increase of the intermodulation distortion is one factor which deteriorates the voice quality of communication apparatuses. In addition, as the moisture resistance of the functional element itself has increased recently, the problem of the signal level of the intermodulation distortion is not negligible in comparison therewith. Because of such circumstances, an electronic device used in a communication apparatus is desired to have improved linearity, i.e., a better intermodulation distortion characteristic.

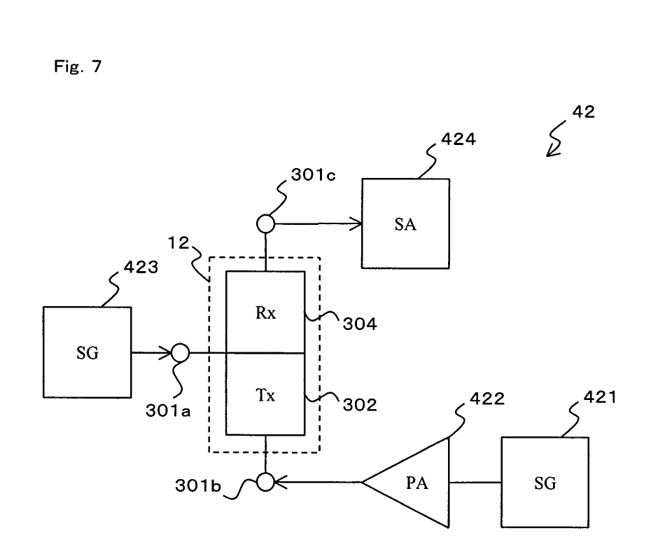

Hereinafter, how much the intermodulation distortion characteristic of the communication apparatus 41 shown in FIG. 5 is improved as compared to that of conventional apparatuses will be described. FIG. 7 shows an exemplary structure of a measurement system 42 for measuring the intermodulation distortion characteristic. As shown in FIG. 7, the measurement system 42 includes a signal generator (SG) 421, a power amplifier (PA) 422, the electronic device 12, a signal generator (SG) 423, and a spectrum analyzer (SA) 424.

Assuming that the North America PCS system is used, a signal in the range of 1850 MHz to 1910 MHz was generated as a transmission signal by the signal generator 421. The passband of the transmission filter 302 was set to be 1850 MHz to 1910 MHz, and the passband of the receiving filter 304 was set to be 1930 MHz to 1990 MHz. The signal generator 421 was controlled such that the level of the transmission signal generated by the signal generator 421 would become 20 dBm at an antenna terminal 301a.

Next, signals having the following frequencies were generated by the signal generator 423 as an interference wave: (fRx−rTx)=80 MHz, (fRx+fTx)=3780 MHz to 3900 MHz, (2fTx−fRx)=1770 MHz to 1830 MHz, and (2fTx+fRx)=5630 MHz to 5810 MHz. fTx is a frequency of the transmission signal transmitted by the signal generator 421, which is within the passband of the transmission filter 302. fRx is a frequency within the passband of the receiving filter 304. The interference wave generated by the signal generator 423 and the transmission signal generated by the signal generator 421 were distorted, and as a result, an intermodulation distortion signal was generated. This intermodulation distortion signal was output to the spectrum analyzer 424 via the receiving filter 304 and a receiving terminal 301b. The intermodulation distortion signal was measured by spectrum analyzer 424.

Where the frequency of the interference wave was (fRx−fTx) and the frequency of the transmission signal was 1850 MHz to 1910 MHz, the signal level of the intermodulation distortion was about −70 dBm to −90 dBm in a conventional duplexer. By contrast, in the electronic device 12, the signal level of the intermodulation distortion was −120 dBm or lower in the entire passband. Thus, it has been confirmed that the intermodulation distortion characteristic of the electronic device 12 is significantly improved.

Where the frequency of the interference wave was (fRx+fTx), the signal level of the intermodulation distortion was about −90 dBm in the conventional duplexer. By contrast, in the electronic device 12, the signal level of the intermodulation distortion was −110 dBm or lower. Where the frequency of the interference wave was (2fTx−fRx), the signal level of the intermodulation distortion was about −80 to −90 dBm in the conventional duplexer. By contrast, in the electronic device 12, the signal level of the intermodulation distortion was −110 dBm or lower. Where the frequency of the interference wave was (2fTx+fRx), the signal level of the intermodulation distortion was about −110 dBm in the conventional duplexer. By contrast, in the electronic device 12, the signal level of the intermodulation distortion was −120 dBm or lower.

The measurement system for the intermodulation distortion characteristic is not limited to the measurement system 42 shown in FIG. 7. For example, an isolator or a band-pass filter is preferably used as necessary in order to protect the measurement system 42.

In the above, the measurement of the intermodulation distortion characteristic of a duplexer is described with reference to FIG. 7. The intermodulation distortion characteristic of the electronic device 11 can be measured in substantially the same manner as that of the electronic device 12 by inputting a signal having a frequency within the passband of the band-pass filter (desired wave) and a signal having a frequency outside the passband of the band-pass filter (interference wave) to the electronic device 11. Regarding the electronic device 11, no specific description of the measurement of the intermodulation characteristic will be given, but substantially the same effects as those for the electronic device 12 is provided.

(Mechanical Switch)

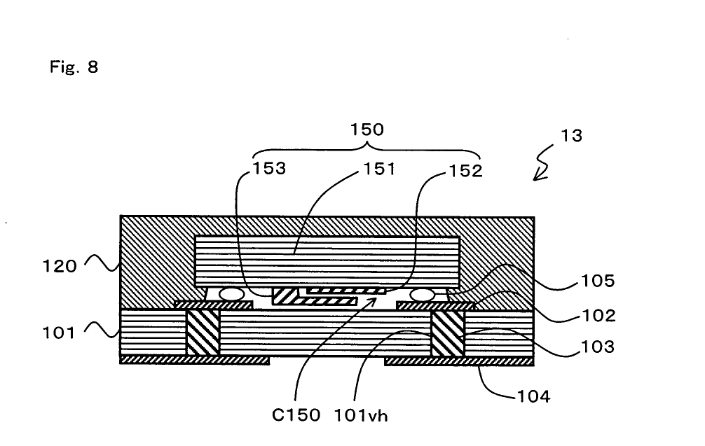

With reference to FIG. 8, a case in which the electronic device according to this embodiment includes a mechanical switch will be described. FIG. 8 is a cross-sectional view showing an exemplary structure of an electronic device 13 according to this embodiment, which includes a mechanical switch. As shown in FIG. 8, the electronic device 13 includes a wiring substrate 101, an internal terminal 102, a wiring electrode 103, an external terminal 104, a conductive bump 105, a functional element 150, and a resin member 120. The electronic device 13 is mainly different from the electronic device 11 shown in FIG. 1 in including the functional device 150 instead of the functional element 110. In FIG. 8, identical elements to those of the electronic device 11 shown in FIG. 1 bear identical reference numerals thereto, and detailed descriptions thereof will be omitted.

The functional element 150 includes a base substrate 151, a fixed electrode 152, and a movable electrode 153. The base substrate 151 is, for example, a silicon substrate. The fixed electrodes 152 and the movable electrodes 153, which are base electrodes, are formed of an electrode material such as gold or the like. The fixed electrode 152 is formed to be fixed on a lower surface of the base substrate 151 by patterning using a micromachining technology. A part of the movable electrode 153 is formed to be fixed on the lower surface of the base substrate 151 by patterning using a micromachining technology. The remaining part of the movable electrode 153 is formed by patterning so as to face the fixed electrode 152, with a gap interposed therebetween. On the lower surface of the base substrate 151, electrode pads are provided in addition to the fixed electrode 152 and the movable electrode 153. The functional element 150 is mounted on the wiring substrate 101 in a face-down manner, with the conductive bump 105 interposed therebetween. A cavity C150 is provided between a lower surface of the functional element 150 and an upper surface of the wiring substrate 101, in order not to inhibit mechanical vibration of the functional element 150. The resin member 120 is formed on the upper surface of the wiring substrate 101 so as to package the functional element 150 and the cavity C150.

The electronic device 13 having such a structure operates as follows. When an electrostatic force is applied to the fixed electrode 152 and the movable electrode 153, the remaining part of the movable electrode 153 is moved to contact the fixed electrode 152. Thus, the fixed electrode 152 and the movable electrode 153 are electrically connected to each other. Namely, the switch is turned ON. In this manner, an electrostatic force is applied to the fixed electrode 152 and the movable electrode 153, so that the functional element 150 acts to be mechanically switched ON or OFF. Namely, the functional element 150 acts as a mechanical switch.

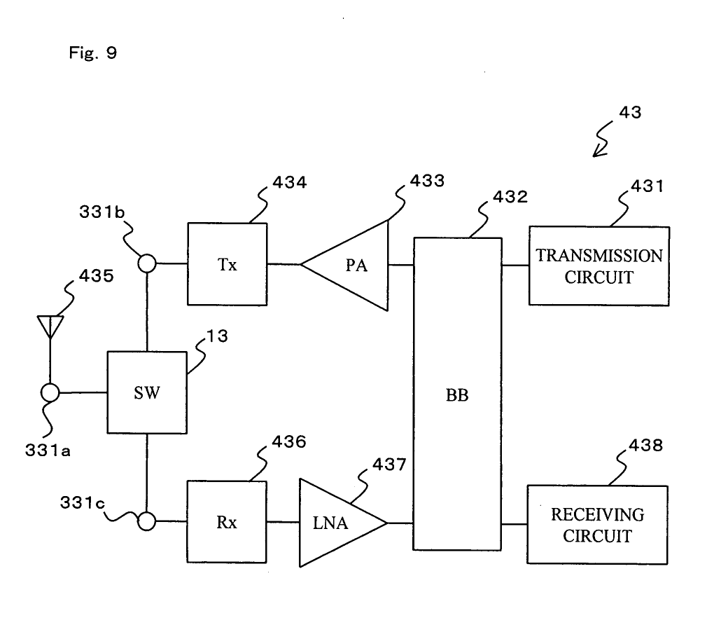

FIG. 9 is a functional block diagram of a communication apparatus 43 including the electronic device 13 shown in FIG. 8. As shown in FIG. 9, the communication apparatus 43 includes a transmission circuit 431, a baseband (BB) section 432, a power amplifier (PA) 433, a transmission filter 434, the electronic device 13, an antenna 435, a receiving filter 436, a low noise amplifier (LNA) 437, and a receiving circuit 438. Referring to FIG. 9, an antenna terminal 331a connected to the antenna 435, a transmission terminal 331b to which a transmission signal is input, and a receiving terminal 331c for outputting a receiving signal are each formed of an electrode pad formed on the lower surface of the base substrate 151. The electronic device 13 includes a switch circuit for connecting the transmission terminal 331b and the antenna terminal 331a to each other at the time of transmission, and for connecting the receiving terminal 331c and the antenna terminal 331a at the time of receiving.

A transmission signal is transmitted as follows. The transmission signal which is output from the transmission circuit 431 is modified by the baseband section 432, and is amplified by the power amplifier 433. The transmission signal which is amplified by the power amplifier 433 is filtered by the transmission filter 434, and is input to the transmission terminal 331b. At the time of transmission, the electronic device 13 connects the transmission terminal 331b and the antenna terminal 331a to each other. Therefore, the transmission signal which is filtered by the transmission filter 434 is transmitted as a radio wave from the antenna 435 via the transmission terminal 331b, the electronic device 13 and the antenna terminal 331a.

At the time of receiving, the electronic device 13 connects the receiving terminal 331c and the antenna terminal 331a to each other. Therefore, a receiving signal which is received by the antenna 435 is output to the receiving filter 436 via the antenna terminal 331a, the electronic device 13 and the receiving terminal 331c, without being input to the transmission filter 434. The receiving signal which is output to the receiving filter 436 is filtered by the receiving filter 436, and is output to the low noise amplifier 437. The receiving signal which is output to the low noise amplifier 437 is amplified by the low noise amplifier 437, and is demodulated by the baseband section 432. The receiving signal which is demodulated by the baseband section 432 is output to the receiving circuit 438. In this manner, the electronic device 13 is used in the communication apparatus 43 as a mechanical switch for transmission and receiving signals in a time division manner.

As a result of measuring the intermodulation distortion characteristic of the communication apparatus 43 shown in FIG. 9, it was found that the signal level of the intermodulation distortion caused by various interference waves is lower by about 10 dBm to 40 dBm as compared to a communication apparatus including a conventional electronic device in which the resin member does not contain a filler formed of a magnetic material.

As described above, in the electronic devices 11 through 13, the resin member 120 contains a filler formed of a magnetic material. This improves the nonlinearity of the electronic device and, when the electronic device is used in a communication apparatus, significantly improves the intermodulation distortion characteristic against various interference waves. Owing to this, the electronic devices 11 through 13 according to this embodiment can be reduced in size and thickness while preventing the intermodulation distortion characteristic from being deteriorated. Since the resin member 120 contains a filler formed of a magnetic material, the electronic devices 11 through 13 according to this embodiment can improve the attenuation outside the passband of the electronic devices and the radio frequency range characteristics including isolation. Communication apparatuses including the electronic devices 11 through 13 according to this embodiment provide high voice quality.

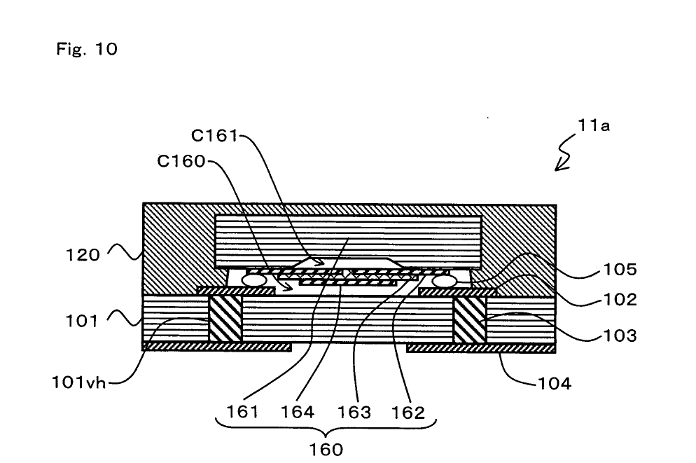

In the above, a surface acoustic wave element is used as the functional element. When a film bulk acoustic wave element is used as the functional element, substantially the same effects are provided. Hereinafter, with reference to FIG. 10 and FIG. 11, an electrode including a film bulk acoustic wave element as a functional element will be described. FIG. 10 is a cross-sectional view showing an exemplary structure of an electronic device 11a including a filter using a film bulk acoustic wave element. FIG. 11 is a cross-sectional view showing an exemplary structure of an electronic device 12a including a duplexer using a film bulk acoustic wave element.

As shown in FIG. 10, the electronic device 11a includes a wiring substrate 101, an internal terminal 102, a wiring electrode 103, an external terminal 104, a conductive bump 105, a resin member 120, and a functional element 160. In FIG. 10, identical elements to those of the electronic device 11 shown in FIG. 1 bear identical reference numerals thereto, and detailed descriptions thereof will be omitted.

The functional element 160 includes a base substrate 161, a first base electrode 162, a piezoelectric layer 163, and a second base electrode 164. The base substrate 161 is formed of silicon, sapphire, glass or the like. The first base electrode 162 and the second base electrode 164 are formed of, for example, molybdenum (Mo). The first base electrode 162 is formed on a lower surface of the base substrate 161 by patterning. The piezoelectric layer 163 is formed on a lower surface of the first base electrode 162. The piezoelectric layer 163 is formed of aluminum nitride (AlN), zinc oxide (ZnO), lead zirconate titanate (PZT) or the like. The second base electrode 164 is formed on a lower surface of the base substrate 161 by patterning so as to interpose the piezoelectric layer 163 between the second base electrode 164 and the first base electrode 162. In the functional element 160, a plurality of film bulk acoustic resonators are formed of the first base electrode 162, the piezoelectric layer 163 and the second base electrode 164. The plurality of film bulk acoustic resonators are electrically connected to one another, so that the functional element 160 acts as a filter. Thus, the electronic device 11a includes the filter. The resonant frequency of a film bulk acoustic resonator is determined by the thickness thereof. The film bulk acoustic resonators are formed on the lower surface of the base substrate 161, with an insulating layer (not shown) interposed therebetween by, for example, a conventional process of etching a sacrifice layer. Among the components of the film bulk acoustic resonators, the first base electrode 162 and the second base electrode 164 are respectively formed on upper and lower surfaces of the piezoelectric layer 163 by sputtering as in the case of the base electrode 112.

A cavity C161 is provided below the lower surface of the base substrate 161, in order not to inhibit elastic vibration of the film bulk acoustic resonators. The cavity C161 is formed by anisotropic etching. Instead of forming the cavity C161 below the base substrate 161, a plurality of layers having different acoustic impedances may be provided as an acoustic mirror. A cavity C160 is provided between a lower surface of the functional element 160 and an upper surface of the wiring substrate 101, in order not to inhibit elastic vibration of the functional element 160. The resin 120 is formed on the upper surface of the wiring substrate 101 so as to package the functional element 160 and the cavity C160.

As shown in FIG. 11, the electronic device 12a includes a wiring substrate 101, an internal terminal 102, a wiring electrode 103, an external terminal 104, a conductive bump 105, an internal layer electrode 107, a resin member 120, and functional elements 160a and 160b. In FIG. 11, identical elements to those of the electronic device 12 shown in FIG. 3 bear identical reference numerals thereto, and detailed descriptions thereof will be omitted.

The functional element 160a includes a base substrate 161a, a first base electrode 162a, a piezoelectric layer 163a, and a second base electrode 164a. In the functional element 160a, a plurality of film bulk acoustic resonators are formed of the first base electrode 162a, the piezoelectric layer 163a and the second base electrode 164a. The plurality of film bulk acoustic resonators are electrically connected to one another, so that the functional element 160a acts as a transmission filter (Tx), which is a band-pass filter having a predetermined passband. The functional element 160a is mounted on the wiring substrate 101 in a face-down manner, with the conductive bump 105 interposed therebetween. A cavity C161a is provided below a lower surface of the base substrate 161a, in order not to inhibit elastic vibration of the film bulk acoustic resonators. A cavity C160a is provided between a lower surface of the functional element 160a and an upper surface of the wiring substrate 101, in order not to inhibit elastic vibration of the functional element 160a. The functional element 160b includes a base substrate 161b, a first base electrode 162b, a piezoelectric layer 163b, and a second base electrode 164b. In the functional element 160b, a plurality of film bulk acoustic resonators are formed of the first base electrode 162b, the piezoelectric layer 163b and the second base electrode 164b. The plurality of film bulk acoustic resonators are electrically connected to one another, so that the functional element 160b acts as a receiving filter (Rx), which is a band-pass filter having a passband which is different from that of the transmission filter (Tx). The functional element 160b is mounted on the wiring substrate 101 in a face-down manner, with the conductive bump 105 interposed therebetween. A cavity C161b is provided below a lower surface of the base substrate 161b, in order not to inhibit elastic vibration of the film bulk acoustic resonators. A cavity C160b is provided between a lower surface of the functional element 160b and the upper surface of the wiring substrate 101, in order not to inhibit elastic vibration of the functional element 160b. The resin member 120 is provided on the upper surface of the wiring substrate 101 so as to package the functional element 160a, the cavity C160a, the functional element 160b and the cavity C160b.

In the above, the functional elements 110, 110a, 110b, 150, 160, 160a and 160b are mounted in a face-down manner. The present invention is not limited to this. For example, in FIG. 1, in the case where the base electrode 112 can be directly molded by the resin member 120 with no problem, or in the case where the functional member 110 has a separate mechanism capable of obtaining a cavity between the base electrode 112 and the resin member 120, the functional element 110 may be mounted on the wiring substrate 101 upside down from the manner shown in FIG. 1. In this case, the base substrate 111 may be directly bonded and fixed to the wiring substrate 101 without using the conductive bump 105, and the base electrode 112 and the internal terminal 102 may be electrically connected to each other by wire bonding or the like. With such a mounting system also, substantially the same effects as the case of the face-down mounting are provided by molding the functional element 110 by the resin member 120.

### Second Embodiment

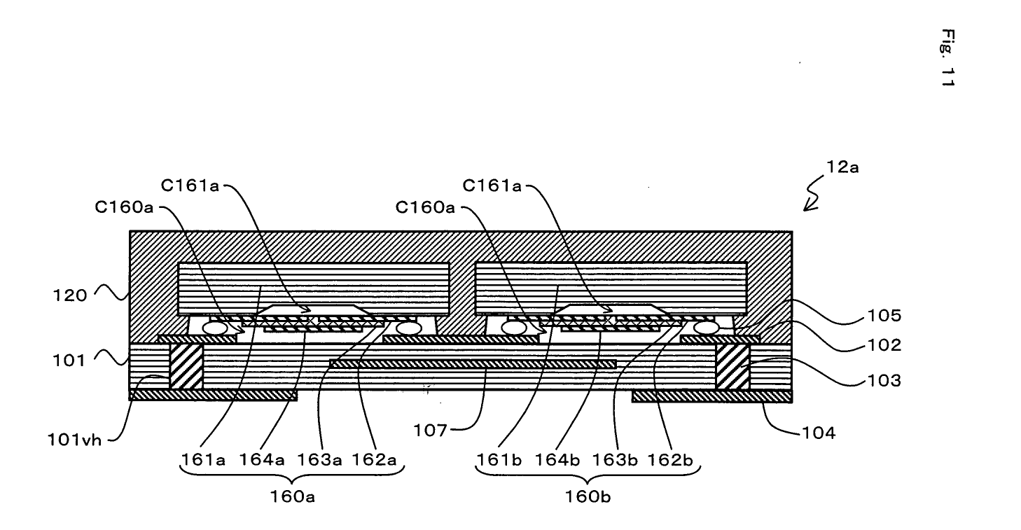

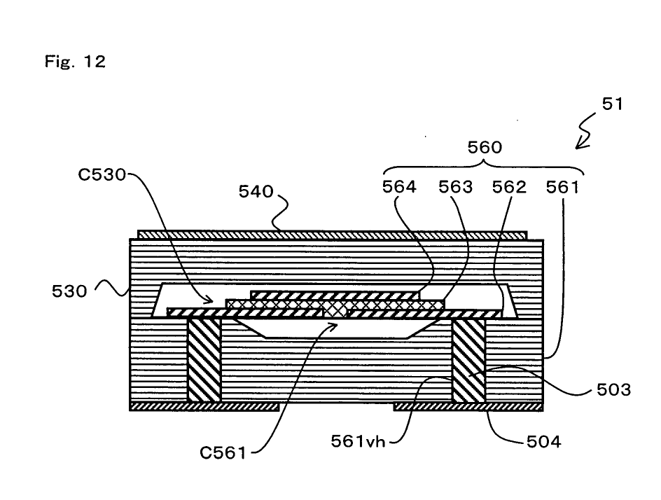

With reference to FIG. 12, an electronic device including a film bulk acoustic wave element as a functional element packaged using a substrate will be described. FIG. 12 is a cross-sectional view showing an exemplary structure of an electronic device 51 including a film bulk acoustic wave element as a functional element packaged using a substrate. As shown in FIG. 12, the electronic device 51 includes a wiring electrode 503, an external terminal 504, a lid substrate 530, a magnetic layer 540, and a functional element 560.

The functional element 560 includes a base substrate 561, a first base electrode 562, a piezoelectric layer 533, and a second base electrode 564. The base substrate 561 is formed of, silicon, sapphire, glass or the like. Via-holes 561vh are formed in the base substrate 561 by deep-RIE. The via-holes 561vh are respectively provided in correspondence with an input pad for inputting an electric signal from outside, an output pad for outputting an electric signal outside, and a grounding pad. The input pad, the output pad, and the grounding pad are provided on an upper surface of the base substrate 561. In each via-hole 561vh, a wiring electrode 503 formed of a conductive material is provided. The wiring electrodes 503 include an input electrode corresponding to the input pad, an output electrode corresponding to the output pad, and a grounding electrode corresponding to the grounding pad. The external terminal 504 is provided on a lower surface of the base substrate 561. The first base electrode 562 is formed on the upper surface of the base substrate 561 by patterning. The external terminal 504 and the first base electrode 562 are electrically connected to each to other via the wiring electrode 503. As understood from this, the wiring electrodes 503 and the external terminal 504 are wiring members for electrically connecting the functional element 560 and an external circuit to each other. The piezoelectric layer 563 is provided on an upper surface of the first base electrode 562. The piezoelectric layer 563 is formed of aluminum nitride (AlN), zinc oxide (ZnO), lead zirconate titanate (PZT) or the like. The second base electrode 564 is formed on an upper surface of the base substrate 561 by patterning so as to interpose the piezoelectric layer 563 between the second base electrode 564 and the first base electrode 562. In the functional element 560, a film bulk acoustic resonator is formed of the first base electrode 562, the piezoelectric layer 563, and the second base electrode 564. The resonant frequency of the film bulk acoustic resonator is determined by the thickness thereof.

The film bulk acoustic resonator is formed on the upper surface of the base substrate 561 with an insulating layer (not shown) interposed therebetween by, for example, a conventional process of etching a sacrifice layer. Among the components of the film bulk acoustic resonator, the first base electrode 562 and the second base electrode 564 are respectively formed on upper and lower surfaces of the piezoelectric layer 563 by sputtering as in the case of the base electrode 112.

A cavity C561 is provided above the upper surface of the base substrate 561, in order not to inhibit elastic vibration of the film bulk acoustic resonator. The cavity C561 is formed by anisotropic etching or the like. Instead of forming the cavity C561 above the base substrate 561, a plurality of layers having different acoustic impedances may be provided as an acoustic mirror.

The lid substrate 530 is formed of substantially the same material as that of the base substrate 561. A lower surface of the lid substrate 530 is bonded to the upper surface of the base substrate 561. The lid substrate 530 and the base substrate 561 may be bonded to each other, for example, with glass frit or a metal layer, using covalent bond by surface activity, or using an organic adhesive. A cavity C530 is provided below the lower surface of the lid substrate 530, in order not to inhibit elastic vibration of the film bulk acoustic resonator. The cavity C530 is formed using anisotropic etching or the like by forming a recess in the lower surface of the lid substrate 530. The lid substrate 530 is a substrate having a recess such that elastic vibration of the film bulk acoustic resonator is not inhibited, and corresponds to a recessed substrate according to the present invention.

The magnetic layer 540 is formed of a magnetic material. As the magnetic material, iron (Fe), permalloy (Fe—Ni), MnZn ferrite, chromium oxide or the like is usable. More specifically, the magnetic material has a chemical formula including at least one chemical element selected from nickel (Ni), iron (Fe), chromium (Cr), cobalt (Co) and manganese (Mn). The magnetic layer 540 is provided on an upper surface of the lid substrate 530 by ion plating. Other methods are also usable instead of ion plating.

The magnetic layer 540 may be formed of an organic material carrying a magnetic metal as a magnetic material. The magnetic layer 540 may be formed of a plurality of laminated layers. A protection layer formed of an insulating inorganic material such as silicon oxide, silicon nitride or the like may be provided around the magnetic layer 540.

Next, a method for producing the electronic device 51 shown in FIG. 12 will be generally described. First, the via-holes 561vh are formed in the base substrate 561 by deep-RIE. Then, the wiring electrodes 503 are respectively formed in the via-holes 561vh formed in the base substrate 561. The external terminal 504 is formed on the lower surface of the base substrate 561. Next, the cavity C561 is formed in the upper surface of the base substrate 561 by anisotropic etching or the like. Then, the first base electrode 562, the piezoelectric layer 563 and the second base electrode 564 are formed on the upper surface of the base substrate 561. The lower surface of the lid substrate 530 and the upper surface of the base substrate 561 are bonded together, such that the first base electrode 562, the piezoelectric layer 563 and the second base electrode 564 are located in the cavity C530 of the lid substrate 530. Then, the magnetic layer 540 is formed on the upper surface of the lid substrate 530 by ion plating. Thus, the electronic device 51 shown in FIG. 12 is obtained.

Next, exemplary cases in which the electronic device according to this embodiment includes each of a filter, a duplexer, and a mechanical switch will be described.

(Filter)

With reference to FIG. 12 again, a case in which the electronic device according to this embodiment includes a filter will be described. In this case, the electronic device 51 includes a plurality of first base electrodes 562, a plurality of piezoelectric layer 563, and a plurality of second base electrode 564. Thus, in the functional element 560, a plurality of film bulk acoustic resonators are provided. The plurality of film bulk acoustic resonators are electrically connected to one another, so that the functional element 560 acts as a filter. Thus, the electronic device 51 includes a filter. As in the first embodiment, the functional element 560 may act as, for example, a high-pass filter, a low-pass filter or a band-pass filter. Referring to FIG. 2A and FIG. 2B, for allowing the functional element 560 to act as a band-pass filter, the series resonators 202a, 202b and 202c and the parallel resonators 203a and 203b are each formed of a film bulk acoustic resonator, and the plurality of film bulk acoustic resonators are electrically connected to one another. An input terminal 201a corresponds to the input pad, an output terminal 201b corresponds to the output pad, and a grounding terminal 201c corresponds to the grounding pad.

(Duplexer)

With reference to FIG. 13, a case in which the electronic device according to this embodiment includes a duplexer will be described. FIG. 13 is a cross-sectional view showing an exemplary structure of an electronic device 52 according to this embodiment, which includes a duplexer. As shown in FIG. 13, the electronic device 52 includes a base substrate 561, a wiring electrode 503, an external terminal 504, a lid substrate 530, a magnetic layer 540, first base electrodes 562a and 562b, piezoelectric layers 563a and 563b, and second base electrodes 564a and 564b. The electronic device 52 is mainly different from the electronic device 51 shown in FIG. 12 in including the first base electrodes 562 and 562b, the piezoelectric layers 563a and 563b, the second base electrodes 564a and 564b, and an internal layer electrode (not shown). In FIG. 13, identical elements to those of the electronic device 51 shown in FIG. 12 bear identical reference numerals thereto, and detailed descriptions thereof will be omitted.

As shown in FIG. 13, a functional element includes the base substrate 561, the first base electrodes 562a and 562b, the piezoelectric layers 563a and 563b, and the second base electrodes 564a and 564b. The base substrate 561 is, for example, a silicon substrate. Cavities C561a and C561b are provided above an upper surface of the base substrate 561. A plurality of film bulk acoustic resonators are formed of the first base electrode 562a, the piezoelectric layer 563a and the second base electrode 564a. The plurality of film bulk acoustic resonators are electrically connected to one another, so that a part of the functional element acts as a transmission filter (Tx), which is a band-pass filter having a predetermined passband. A cavity C530a is provided below a lower surface of the lid substrate 530 in positional correspondence with the second base electrode 564a, and a cavity C530b is also provided below the lower surface of the lid substrate 530 in positional correspondence with the second base electrode 564b. A plurality of film bulk acoustic resonators are formed of the first base electrode 562b, the piezoelectric layer 563b and the second base electrode 564b. The plurality of film bulk acoustic resonators are electrically connected to one another, so that another part of the functional element acts as a receiving filter (Rx), which is a band-pass filter having a passband which is different from that of the transmission filter (Tx). The internal layer electrode (not shown) formed in the base substrate 561 forms a phase shift circuit (transmission line). In this manner, the functional element shown in FIG. 13 acts a duplexer including a transmission filter, a receiving filter, and a phase shift circuit. Thus, the electronic device 52 includes a duplexer. The magnetic layer 540 is provided on an upper surface of the lid substrate 530.

In FIG. 13, one electronic device 52 includes a duplexer, but the duplexer is not limited to this. For example, a duplexer may be formed by connecting an electronic device 51 including a transmission filter and another electronic device 51 including a receiving filter to each other on another substrate such as a mother substrate or the like. The structure shown in FIG. 13 in which one electronic device 52 includes a duplexer has a smaller size.

The electronic device 52 shown in FIG. 13 can be represented by the functional block diagram in FIG. 4. Referring to FIG. 4, a transmission filter (Tx) 302 is formed of the first base electrode 562a, the piezoelectric layer 563a, and the second base electrode 564a. A phase shift circuit 303 is formed of the internal layer electrode (not shown). A receiving filter (Rx) 304 is formed of the first base electrode 562b, the piezoelectric layer 563b, and the second base electrode 564b. A communication apparatus including the electronic device 52 shown in FIG. 13 may be represented by the functional block diagram in FIG. 5, except that the electronic device 12 is replaced with the electronic device 52.

Hereinafter, how much the intermodulation distortion characteristic (described in the first embodiment) of a communication apparatus including the electronic device 52 is improved as compared to that of conventional apparatuses will be described. For measuring the intermodulation distortion characteristics, a system as shown in FIG. 7 was used except that the electronic device 12 was replaced with the electronic device 52.

Where the frequency of the interference wave was (fRx−fTx) and the frequency of the transmission signal was 1850 MHz to 1910 MHz, the signal level of the intermodulation distortion was about −70 dBm to −80 dBm in a conventional duplexer. By contrast, in the electronic device 52, the signal level of the intermodulation distortion was −120 dBm or lower in the entire passband. Thus, it has been confirmed that the intermodulation distortion characteristic of the electronic device 52 is significantly improved.

Where the frequency of the interference wave was (fRx+fTx), the signal level of the intermodulation distortion was about −80 dBm in the conventional duplexer. By contrast, in the electronic device 52, the signal level of the intermodulation distortion was −110 dBm or lower. Where the frequency of the interference wave was (2fTx−fRx), the signal level of the intermodulation distortion was about −70 to −95 dBm in the conventional duplexer. By contrast, in the electronic device 52, the signal level of the intermodulation distortion was −120 dBm or lower. Where the frequency of the interference wave was (2fTx+fRx), the signal level of the intermodulation distortion was about −100 dBm in the conventional duplexer. By contrast, in the electronic device 52, the signal level of the intermodulation distortion was −120 dBm or lower.

In the above, the measurement of the intermodulation distortion characteristic of a duplexer is described. The intermodulation distortion characteristic of the electronic device 51 can be measured in substantially the same manner as that of the electronic device 52 by inputting a signal having a frequency within the passband of the band-pass filter (desired wave) and a signal having a frequency outside the passband of the band-pass filter (interference wave) to the electronic device 51. Regarding the electronic device 51, no specific description of the measurement of the intermodulation characteristic will be given, but substantially the same effects as those for the electronic device 52 is provided.

(Mechanical Switch)

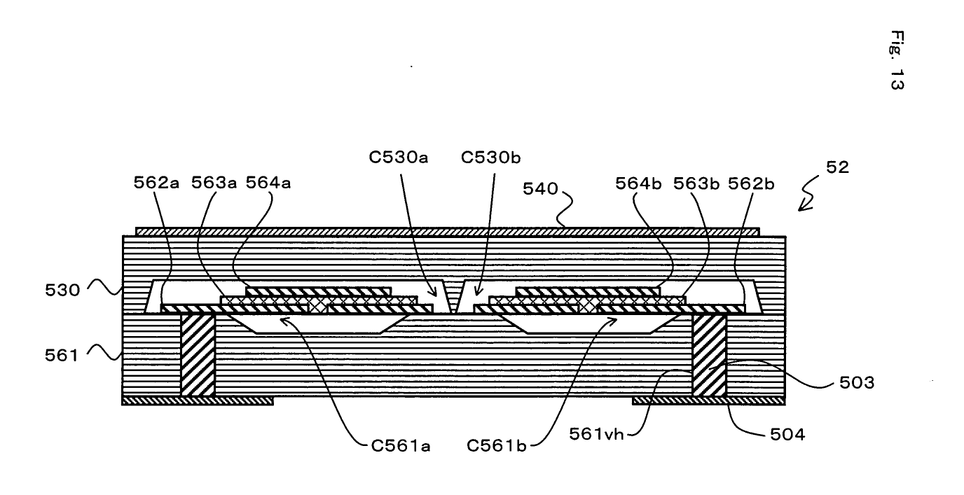

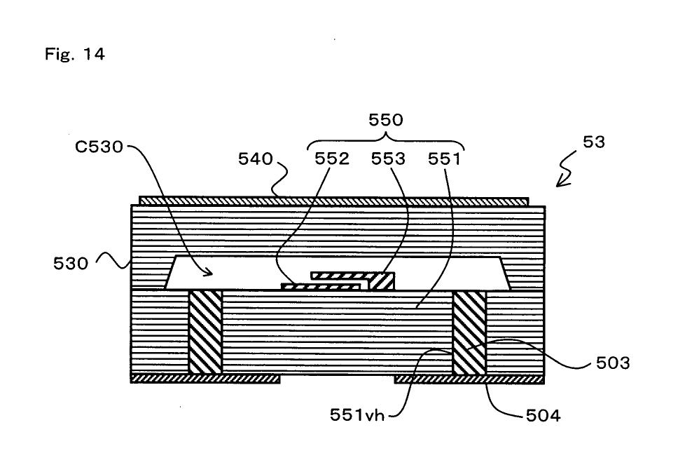

With reference to FIG. 14, a case in which the electronic device according to this embodiment includes a mechanical switch will be described. FIG. 14 is a cross-sectional view showing an exemplary structure of an electronic device 53 according to this embodiment, which includes a mechanical switch. As shown in FIG. 14, the electronic device 53 includes a wiring electrode 503, an external terminal 504, a lid substrate 530, a magnetic layer 540, and a functional element 550. The electronic device 53 is mainly different from the electronic device 51 shown in FIG. 12 in including the functional device 550 instead of the functional element 560. In FIG. 14, identical elements to those of the electronic device 51 shown in FIG. 12 bear identical reference numerals thereto, and detailed descriptions thereof will be omitted.

The functional element 550 includes a base substrate 551, a fixed electrode 552, and a movable electrode 553. The base substrate 551 is, for example, a silicon substrate. The fixed electrode 552 and the movable electrode 553, which are base electrodes, are formed of an electrode material such as gold or the like. The fixed electrode 552 is formed to be fixed on an upper surface of the base substrate 551 by patterning using a micromachining technology. A part of the movable electrode 553 is formed to be fixed on the upper surface of the base substrate 551 by patterning using a micromachining technology. The remaining part of the movable electrode 553 is formed by patterning so as to face the fixed electrode 552, with a gap interposed therebetween. On the upper surface of the base substrate 551, electrode pads are provided in addition to the fixed electrode 552 and the movable electrode 553. A cavity C530 is provided below a lower surface of the lid substrate 530. The magnetic layer 540 is provided on an upper surface of the lid substrate 530. When an electrostatic force is applied to the fixed electrode 552 and the movable electrode 553, the functional element 550 acts to be mechanically switched ON or OFF. Namely, the functional element 550 acts as a mechanical switch.

A communication device including the electronic device 53 shown in FIG. 14 can be represented by the functional block diagram in FIG. 9, except that the electronic device 13 of the communication device 43 is replaced with the electronic device 53. In the case where the electronic device 53 shown in FIG. 14 is used, an antenna terminal 331a, a transmission terminal 331b and a receiving terminal 331c are each formed of an electrode pad formed on the upper surface of the base substrate 551. The electronic device 53 includes a switch circuit for connecting the transmission terminal 331b and the antenna terminal 331a to each other at the time of transmission, and for connecting the receiving terminal 331c and the antenna terminal 331a at the time of receiving. An operation of the communication apparatus including the electronic device 53 shown in FIG. 14 is substantially the same as that of the communication apparatus 43 shown in FIG. 9, and will not be described again.

As a result of measuring the intermodulation distortion characteristic of the communication apparatus including the electronic device 53, it was found that the signal level of the intermodulation distortion caused by various interference waves is lower by about 20 dBm to 50 dBm as compared to a communication apparatus including a conventional electronic device in which the magnetic layer 540 is not provided on the upper surface of the lid substrate 530.

As described above, in the electronic devices 51 through 53, the magnetic layer 540 is provided on the upper surface of the lid substrate 530. This improves the nonlinearity of the electronic device and, when the electronic device is used in a communication apparatus, significantly improves the intermodulation distortion characteristic against various interference waves. Owing to this, the electronic devices 51 through 53, according to the present invention, each including a functional element packaged using a substrate, can significantly improve the intermodulation distortion characteristic. In addition, since the step of forming the magnetic layer 540 on the upper surface of the lid substrate 530 is simple, the electronic devices 51 through 53 according to this embodiment can improve the intermodulation distortion characteristic at low cost. Communication apparatuses including the electronic devices 51 through 53 according to this embodiment provide high voice quality.

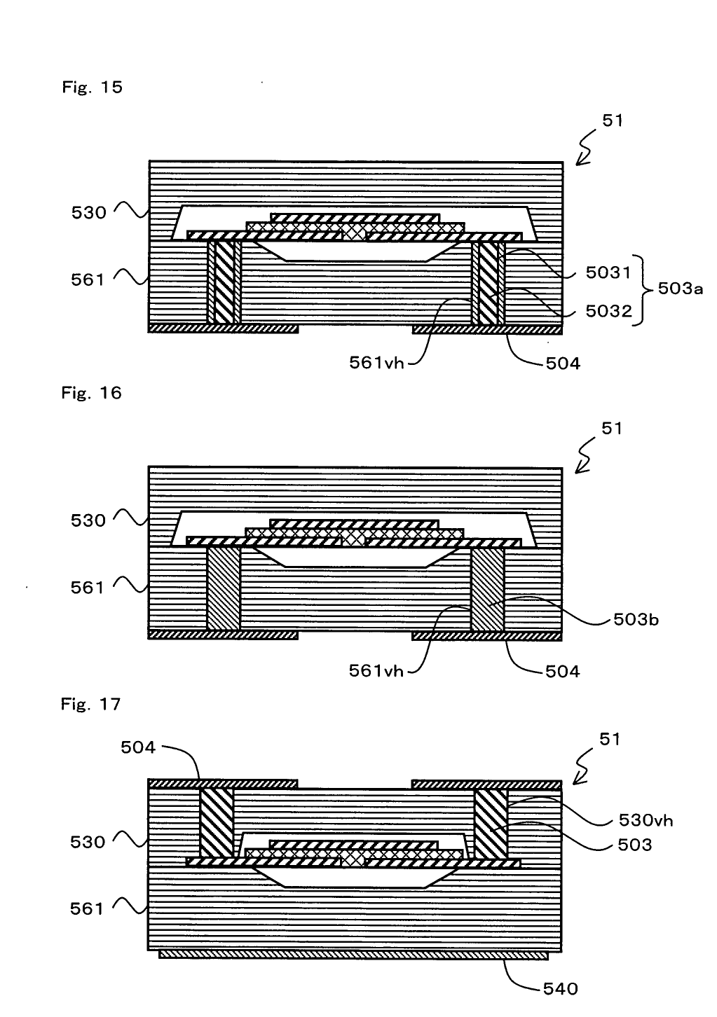

In the electronic devices 51 through 53, the intermodulation distortion characteristic is improved by providing the magnetic layer 540 on the upper surface of the lid substrate 530. The present invention is not limited to this. For example, as shown in FIG. 15 and FIG. 16, at least a part of the wiring electrode 503 may be formed of a magnetic material. In this case also, substantially the same effects are provided as those in the case where the magnetic layer 540 is provided on the upper surface of the lid substrate 530. FIG. 15 is a cross-sectional view showing an exemplary structure of an electronic device 51 in which a magnetic layer 5031 is provided on a sidewall of the via-hole 561vh. FIG. 16 is across-sectional view showing an exemplary structure of an electronic device 51 in which the wiring electrode 503 is entirely formed of a magnetic material.

As shown in FIG. 15, the wiring electrode 503a includes the magnetic layer 5031 and a conductive member 5032. The magnetic layer 5031 is in an outer part of the wiring electrode 503a and is in contact with the via-hole 561vh. In FIG. 15, the magnetic layer 5031 covers the entire side wall of the via-hole 561vh, but the present invention is not limited to this. The magnetic layer 5031 may be formed on at least a part of the side wall of the via-hole 561vh. In this case, it is preferable that the magnetic layer 5031 is formed to be ring-shaped along the side wall of the via-hole 561vh. Such a structure efficiently improves the intermodulation distortion characteristic with a small number of members. Preferably, the conductive member 5032 is formed of a non-magnetic material such as silver, copper or the like. With such a structure, the electronic device 51 has a small conductor loss, and superb intermodulation distortion and other radio frequency range characteristics. In this case, the magnetic layer 5031 may be formed of an organic material carrying a magnetic metal as a magnetic material. A protection layer formed of an insulating inorganic material such as silicon oxide, silicon nitride or the like may be provided around the magnetic layer 5031. In FIG. 16, the wiring electrode 503b is entirely formed of a conductive magnetic material.

In the case where at least a part of the wiring electrode 503 is formed of a magnetic material, it is preferable that at least a part of an input electrode included in the wiring electrodes 503 is formed of a magnetic material. Alternatively, it is preferable that at least a part of an output electrode included in the wiring electrodes 503 is formed of a magnetic material. Still alternatively, at least a part of the input electrode and at least a part of the output electrode may be formed of a magnetic material. Such a structure efficiently improves the intermodulation distortion characteristic.

For example, at least a part of the external terminal 504 may be formed of a magnetic material. As shown in FIG. 17, via-holes may be formed in the lid substrate 530. FIG. 17 is a cross-sectional view showing an exemplary structure of an electronic device 51 in which the lid substrate 530 has via-holes 530vh therein. In this case, the wiring electrode 503 is provided in each of the via-holes 530vh formed in the lid substrate 530. As shown in FIG. 17, the external terminal 504 is provided on an upper surface of the lid substrate 530. The magnetic layer 540 is provided on a lower surface of the base substrate 561. In the structure shown in FIG. 17, the magnetic layer 540 may be provided on an area of the upper surface of the lid substrate 530, which does not have the external terminal 504 thereon, instead of on the lower surface of the base substrate 561. In the case where the magnetic layer 540 formed of an insulating magnetic material is provided between the external terminals 504 on the upper surface of the lid substrate 530, the isolation of the external terminals 504 is improved. In the case where the electronic device 51 includes a filter, the attenuation outside the passband is increased. Owing to these, the electronic device 51 has superb intermodulation distortion and other radio frequency range characteristics.

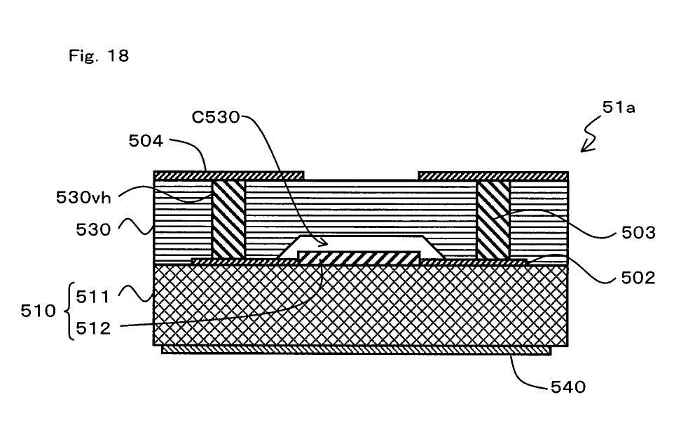

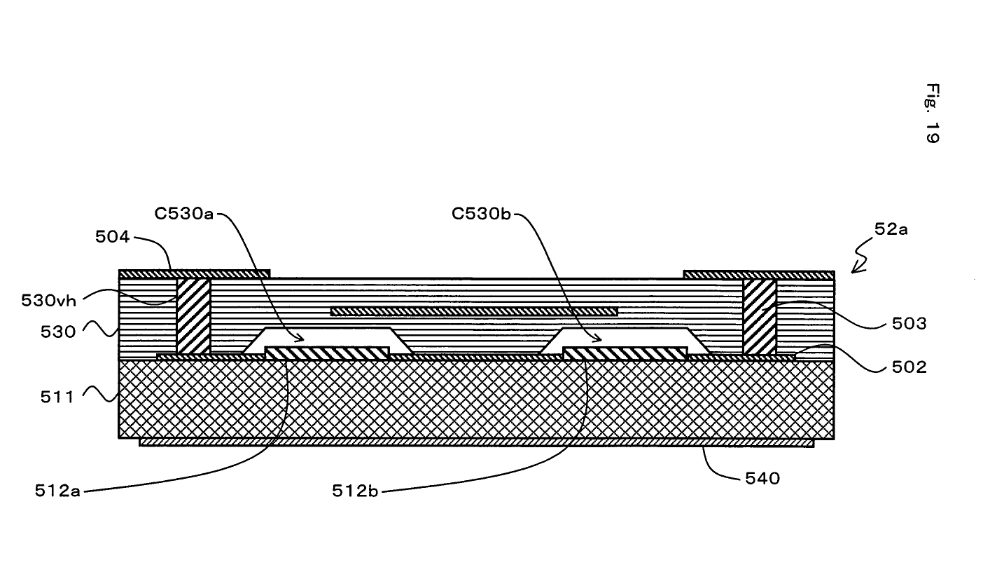

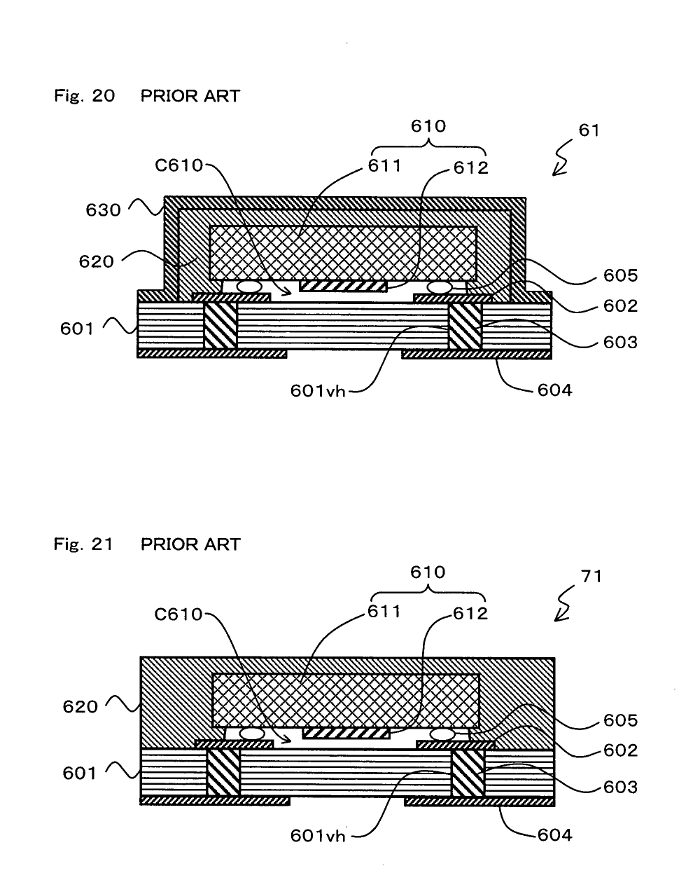

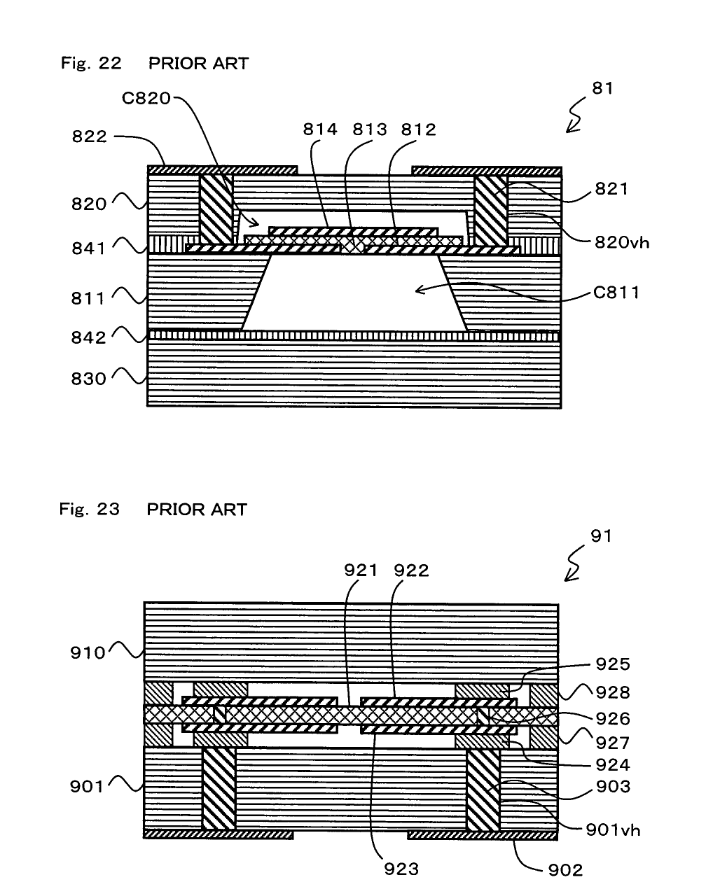

In the above, a film bulk acoustic wave element is used as the functional element. When a surface acoustic wave element is used as the functional element, substantially the same effects are provided. Hereinafter, with reference to FIG. 18 and FIG. 19, an electrode including a surface acoustic wave element as a functional element will be described. FIG. 18 is a cross-sectional view showing an exemplary structure of an electronic device 51a including a filter using a surface acoustic wave element. FIG. 19 is a cross-sectional view showing an exemplary structure of an electronic device 52a including a duplexer using a surface acoustic wave element.

As shown in FIG. 18, the electronic device 51a includes an internal terminal 502, a wiring electrode 503, an external terminal 504, a functional element 510, a lid substrate 530, and a magnetic layer 540. In FIG. 18, identical elements to those of the electronic device 51 shown in FIG. 12 bear identical reference numerals thereto, and detailed descriptions thereof will be omitted.

The functional element 510 includes a base substrate 511 and a base electrode 512. The base substrate 511 is, for example, a piezoelectric substrate. The base electrode 512 is formed of a layer of aluminum or the like, and is provided on an upper surface of the base substrate 511. The base electrode 512 is patterned to form a plurality of comb-like electrodes for exciting a surface acoustic wave and a plurality of electrode pads for electrically connecting the functional element 510 and an external circuit to each other. The electrode pads include an input pad for inputting an electric signal from outside, an output pad for outputting an electric signal to outside, and a grounding pad. In the functional element 510, a surface acoustic wave resonator is formed of a comb-like electrode included in the base electrode 512 and the base substrate 511. In the base electrode 512, a plurality of comb-like electrodes are formed. Thus, in the functional element 510, a plurality of surface acoustic wave resonators are formed of the plurality of comb-like electrodes and the base substrate 511. The plurality of surface acoustic wave resonators are electrically connected to one another, so that the functional element 510 acts as a filter. Thus, the electronic device 51a includes a filter. After the base electrode 512 is formed, a lower surface of the base substrate 511 is processed with back-grinding by chemical mechanical polishing (CMP). In this embodiment, the base substrate 511 is processed to have a thickness of about 150 μM.

A lower surface of the lid substrate 530 is bonded to the upper surface of the base substrate 511. A cavity C530a is provided below the lower surface of the lid substrate 530, in order not to inhibit elastic vibration of the surface acoustic resonators. Generally, a piezoelectric substrate is difficult to be processed. Therefore, the via-holes 530vh, the internal terminal 502, the external terminal 504 and the cavity C530 are formed in or on the lid substrate 530 formed of silicon. The wiring electrode 503 is provided in each via-hole 530vh. The internal terminal 502 and the external terminal 504 are electrically connected to each other via the wiring electrode 503. The magnetic layer 540 is provided on the lower surface of the base substrate 511.

As shown in FIG. 19, the electronic device 52a includes an internal terminal 502, a wiring electrode 503, an external terminal 504, a base substrate 511, base electrodes 512a and 512b, a lid substrate 530, and a magnetic layer 540. In FIG. 19, identical elements to those of the electronic device 52 shown in FIG. 13 bear identical reference numerals thereto, and detailed descriptions thereof will be omitted.

As shown in FIG. 19, a functional element includes the base substrate 511 and the base electrodes 512a and 512b. The base electrode 512a includes a plurality of comb-like electrodes. A plurality of surface acoustic wave resonators are formed of the plurality of comb-like electrodes included in the base electrode 512a and the base substrate 511. The plurality of surface acoustic wave resonators are electrically connected to one another, so that a part of the functional element acts as a transmission filter (Tx), which is a band-pass filter having a predetermined passband. The base electrode 512b includes a plurality of comb-like electrodes. A plurality of surface acoustic wave resonators are formed of the plurality of comb-like electrodes included in the base electrode 512b and the base substrate 511. The plurality of surface acoustic wave resonators are electrically connected to one another, so that another part of the functional element acts as a receiving filter (Rx), which is a band-pass filter having a passband which is different from that of the transmission filter (Tx).

A lower surface of the lid substrate 530 is bonded to the upper surface of the base substrate 511. A cavity C530a is provided below the lower surface of the lid substrate 530 in positional correspondence with the base electrode 512a, in order not to inhibit elastic vibration of the surface acoustic resonators. A cavity C530b is provided below the lower surface of the lid substrate 530 in positional correspondence with the base electrode 512b, in order not to inhibit elastic vibration of the surface acoustic resonators. The internal terminal 502 is provided on the lower surface of the lid substrate 530. The external terminal 504 is provided on an upper surface of the lid substrate 530. In the lid substrate 530, via-holes 530vh are formed. In each via-hole 530vh, the wiring electrode 503 is provided. The internal terminal 502 and the external terminal 504 are electrically connected to each other via the wiring electrode 503. The magnetic layer 540 is provided on a lower surface of the base substrate 511.

As described above, in this embodiment, even when a surface acoustic wave element is used as the functional element, substantially the same effects are provided as those in the case where a film bulk acoustic wave element is used.

While the invention has been described in detail, the foregoing description is in all aspects illustrative and not restrictive. It is understood that numerous other modifications and variations can be devised without departing from the scope of the invention.

What is claimed is:

1. An electronic device including a functional element acting as a predetermined circuit packaged using a resin member, the electronic device comprising:
a wiring substrate having a wiring member for electric connection with an external circuit;
the functional element mounted on one main surface of the wiring substrate so as to be electrically connected to the wiring member; and
the resin member provided on the one main surface of the wiring substrate having the functional element, so as to package the functional element;
wherein the resin member includes a filler formed of a magnetic material.

2. An electronic device according to claim 1, wherein the filler is formed of a conductive magnetic material covered with an insulating material.

3. An electronic device according to claim 1, wherein the filler is formed of an organic material carrying the magnetic material.

4. An electronic device according to claim 1, wherein the magnetic material has a chemical formula including at least one chemical element selected from nickel, iron, chromium, cobalt and manganese.

5. An electronic device according to claim 1, wherein the functional element is a passive element.

6. An electronic device according to claim 1, wherein the functional element acts as a filter using elastic vibration.

7. An electronic device according to claim 1, wherein the functional element acts as a mechanical switch.

8. An electronic device according to claim 1, wherein:
two of the functional element are provided on one main surface of the wiring substrate; and
the two functional elements respectively act as band-pass filters having different passbands from each other.

9. A communication apparatus, comprising:
an antenna;
a transmission circuit;
a receiving circuit; and
an electronic device according to claim 1 in at least one of a connection section of the antenna with the transmission circuit and the receiving circuit, a connection section of the antenna and the transmission circuit, and a connection section of the antenna and the receiving circuit.

10. A method for producing an electronic device including a functional element acting as a predetermined circuit packaged using a resin member, the method comprising the steps of:
mounting the functional element on one main surface of a wiring substrate having a wiring member for electric connection with an external circuit, such that the functional element is electrically connected to the wiring member; and
forming the resin member including a filler formed of a magnetic material on the one main surface of the wiring substrate having the functional element, such that the functional element is packaged.

11. An electronic device including a part of a functional element acting as a predetermined circuit packaged using a recessed substrate having a recess in one main surface thereof, the electronic device comprising:
the functional element including at least a base substrate and a base electrode provided on one main surface of the base substrate, the base electrode having a pattern in accordance with the predetermined circuit;
the recessed substrate provided on the main surface of the base substrate so as to locate the base electrode in the recess and package the base electrode; and
a wiring electrode, provided in a via-hole formed in one of the base substrate and the recessed substrate, for electrically connecting the functional element and an external circuit to each other;
wherein at least a part of the wiring electrode is formed of a magnetic material.

12. An electronic device according to claim 11, further comprising a magnetic layer provided on at least one of, on a main surface of the base substrate opposite to the main surface thereof having the base electrode, and on a main surface of the recessed substrate opposite to the main surface thereof having the recess.

13. An electronic device according to claim 11, wherein at least a part of an outer part of the wiring electrode in contact with the via-hole is formed of a magnetic material.

14. An electronic device according to claim 11, wherein the wiring electrode is entirely formed of a conductive magnetic material.

15. An electronic device according to claim 11, wherein the wiring electrode includes:
an input electrode for inputting an electric signal which is output from the external circuit;
an output electrode for outputting an electric signal to the external circuit; and
a grounding electrode;
wherein at least a part of at least one of the input electrode and the output electrode is formed of a magnetic material.

16. An electronic device according to claim 11, wherein the magnetic material has a chemical formula including at least one chemical element selected from nickel, iron, chromium, cobalt and manganese.

17. An electronic device according to claim 11, wherein a part of the wiring electrode is formed of a magnetic material covered with an insulating material.

18. An electronic device according to claim 11, wherein a part of the wiring electrode is formed of an organic material carrying the magnetic material.

19. An electronic device according to claim 11, wherein the functional element is a passive element.

20. An electronic device according to claim 11, wherein:
the base electrode includes a pattern in accordance with a filter; and
the functional element acts as a filter using elastic vibration.

21. An electronic device according to claim 11, wherein:
the base electrode includes a pattern in accordance with a mechanical switch; and
the functional element acts as a mechanical switch.

22. An electronic device according to claim 11, wherein:
the base electrode includes a plurality of patterns in accordance with band-pass filters having different passbands from each other; and
the functional element acts as a duplexer including the band-pass filters.

23. A communication apparatus, comprising:
an antenna;
a transmission circuit;
a receiving circuit; and
an electronic device according to claim 11 in at least one of a connection section of the antenna with the transmission circuit and the receiving circuit, a connection section of the antenna and the transmission circuit, and a connection section of the antenna and the receiving circuit.

24. A method for producing an electronic device including a part of a functional element acting as a predetermined circuit packaged using a recessed substrate having a recess in one main surface thereof, the method comprising the steps of:
forming a base electrode, including a pattern in accordance with the predetermined circuit of the functional element, on one main surface of the base substrate;
locating the recessed substrate on the main surface of the base substrate so as to locate the base electrode in the recess and package the base electrode;
forming a via-hole in one of the base substrate and the recessed substrate; and
forming a wiring electrode for electrically connecting the functional element and an external circuit to each other in the via-hole, the wiring electrode being at least partially formed of a magnetic material.
